(19) United States
(12) Patent Application Publication
(10) Pub. No.: US 2017/0315201 A1
(43) Pub. Date: Nov. 2, 2017

(54) MAGNETIC RESONANCE IMAGING APPARATUS AND MAGNETIC RESONANCE IMAGING METHOD

(71) Applicant: Hitachi, Ltd., Tokyo (JP)

(72) Inventor: Kosuke HIRAI, Tokyo (JP)

(73) Assignee: Hitachi, Ltd., Tokyo (JP)

(21) Appl. No.: 15/519,946

(22) PCT Filed: Oct. 7, 2015
(86) PCT No.: PCT/JP2015/078467

§ 371 Date: Apr. 18, 2017

(30) Foreign Application Priority Data
Oct. 30, 2014 (JP) 2014-221872

(51) Int. Cl. G01R 33/561; G01R 33/56; G01R 33/565; G01R 33/3415

(52) U.S. Cl. CPC G01R 33/5611; G01R 33/56509; G01R 33/3415; G01R 33/5608; G01R 33/5615

(57) ABSTRACT

In order to remove restriction on the number of additions in imaging for offsetting errors caused by hardware performance and/or signal fluctuation caused by a hardware control method by inverting the polarity of predetermined hardware output, the present invention executes a first imaging sequence and a second imaging sequence in which the polarity of a predetermined gradient magnetic field pulse in the first imaging sequence was inverted, adds data acquired in each imaging sequence, and then acquires addition images. In order to perform the addition, each coefficient is determined so that the total of coefficients by which first data acquired in the first imaging sequence are to be multiplied is equal to the total of coefficients by which second data acquired in the second imaging sequence are to be multiplied.

### TECHNICAL FIELD

The present invention relates to a magnetic resonance imaging (hereinafter, referred to as MRI) technique, and, in particular, to an addition imaging technique for obtaining an addition image by performing imaging for a plurality of times.

### BACKGROUND ART

An FSE (Fast Spin Echo) sequence irradiates refocus RF pulses at certain intervals after irradiating one excitation RF pulse and continuously collects a plurality of NMR signals (echo signals). Since the strength of echo signals to be collected for each refocus RF pulse is attenuated by a T2 value of imaging tissue in the FSE sequence, signal strength differences are generated between echo signals that reconstruct one image, which generates artifacts on the image.

As the counter measure, there is a method of performing addition imaging that obtains and adds a plurality of images by inverting the arrangement of echoes in the time direction in k-space acquired by using a sequence for obtaining the odd-number-th images and a sequence for obtaining the even-number-th images (for example, refer to Patent Literature 1).

An EPI (Echo Planar Imaging) sequence collects a plurality of echo signals by repeatedly inverting the polarity of read-out gradient magnetic field pulses after irradiating excitation RF pulses. In the EPI sequence, phase errors are generated between measured echo signals by inverting the polarity of the read-out gradient magnetic field pulses at a high speed, which generates artifacts on the image.

As the counter measure, there is a method of performing the addition imaging by inverting the polarity of the read-out gradient magnetic field at the same phase encoding amount between the sequence for obtaining the odd-number-th images and the sequence for obtaining the even-number-th images (for example, refer to Patent Literature 2).

### CITATION LIST

### Patent Literature

PTL 1: European Patent No. 1653244

PTL 2: U.S. Pat. No. 7,418,286

### SUMMARY OF INVENTION

### Technical Problem

Both of the above patents have a purpose to offset errors caused by hardware performance and/or signal fluctuation caused by a hardware control method by inverting the polarity of predetermined hardware output before imaging. In this addition imaging, it is presumed that the number of additions is necessarily even numbers.

By the way, the addition imaging is generally performed in order to improve the S/N ratio of images, and the optimal number of times is determined based on the desired image quality and the imaging time. Therefore, the optimal number of additions is not always limited to even numbers. In imaging for offsetting the errors, using the even numbers is a necessary condition, and it is required to sacrifice some condition in order to set the number of additions to an even number in a case where the optimal number of times determined by imaging conditions and the like is not an even number.

The present invention was made in light of the above circumstances and has a purpose to provide a technique for removing restriction on the number of additions in addition imaging for offsetting errors caused by hardware performance and/or signal fluctuation caused by a hardware control method by inverting the polarity of predetermined hardware output before the imaging.

### Solution to Problem

The present invention executes a first imaging sequence and a second imaging sequence in which the polarity of a predetermined gradient magnetic field pulse in the first imaging sequence was inverted, adds data acquired in each imaging sequence, and then obtains addition images. In order to perform the addition, each coefficient is determined so that the total of coefficients by which first data acquired in the first imaging sequence are to be multiplied is equal to the total of coefficients by which second data acquired in the second imaging sequence are to be multiplied.

### Advantageous Effects of Invention

According to the present invention, the technique can perform addition imaging for offsetting errors caused by hardware performance and/or signal fluctuation caused by a hardware control method by inverting the polarity of predetermined hardware output without restriction on the number of additions.

### BRIEF DESCRIPTION OF DRAWINGS

FIG. 1 is a block diagram of the overall configuration of the MRI apparatus in a first embodiment.

FIG. 2 illustrates an FSE sequence.

FIGS. 3(a) and 3(b) illustrate the FSE sequence in the first embodiment.

FIG. 4 illustrates an arrangement order of echo signals in the first embodiment.

FIGS. 5(a) and 5(b) respectively illustrate a signal profile in the ky direction in k-space when a first imaging sequence is executed and a signal profile in the y direction of an image reconstructed from the k-space in addition imaging.

FIGS. 6(a) and 6(b) respectively illustrate a signal profile in the ky direction in k-space when a second imaging sequence is executed and a signal profile in the y direction of an image reconstructed from the k-space in addition imaging.

FIGS. 7(a) and 7(b) respectively illustrate a signal profile in the ky direction in k-space of an addition result of the first and second results and a signal profile in the y direction of an image reconstructed from the k-space in addition imaging.

FIGS. 8(a) and 8(b) respectively illustrate a signal profile in the ky direction in k-space of an addition result of the first, second, and third results using the conventional method and a signal profile in the y direction of an image reconstructed from the k-space in addition imaging.

FIG. 9 is a functional block diagram of an entire control unit of the first embodiment.

FIG. 10 is a flow chart of addition imaging processing in the first embodiment.

FIGS. 11(a) and 11(b) respectively illustrate a signal profile in the ky direction in k-space of an addition result of the first, second, and third results using the method of the present embodiment and a signal profile in the y direction of an image reconstructed from the k-space in addition imaging.

FIG. 12 illustrates examples of coefficients to be calculated in the first embodiment.

FIGS. 13(a) and 13(b) illustrate EPI sequences to be used in the other variations of the first embodiment.

FIG. 14 is a functional block diagram of the entire control unit of a second embodiment.

FIG. 15(a) illustrates an example of an adoption/rejection receiving screen of the second embodiment, and FIG. 15(b) illustrates an example of an end receiving screen of a third embodiment.

FIG. 16 is a flow chart of addition imaging processing in the second embodiment.

FIG. 17 is a flow chart of addition imaging processing in the third embodiment.

FIG. 18 is a flow chart of a modification of addition imaging processing in the second and third embodiments.

### DESCRIPTION OF EMBODIMENTS

### First Embodiment

Hereinafter, an embodiment example of the present invention will be described in detail according to the attached drawings. It is noted that the same reference signs are basically used for that having the same functions in order to omit the repeated descriptions in all the drawings to be used for describing the embodiments of the present invention.

[Block Diagram of MRI Apparatus]

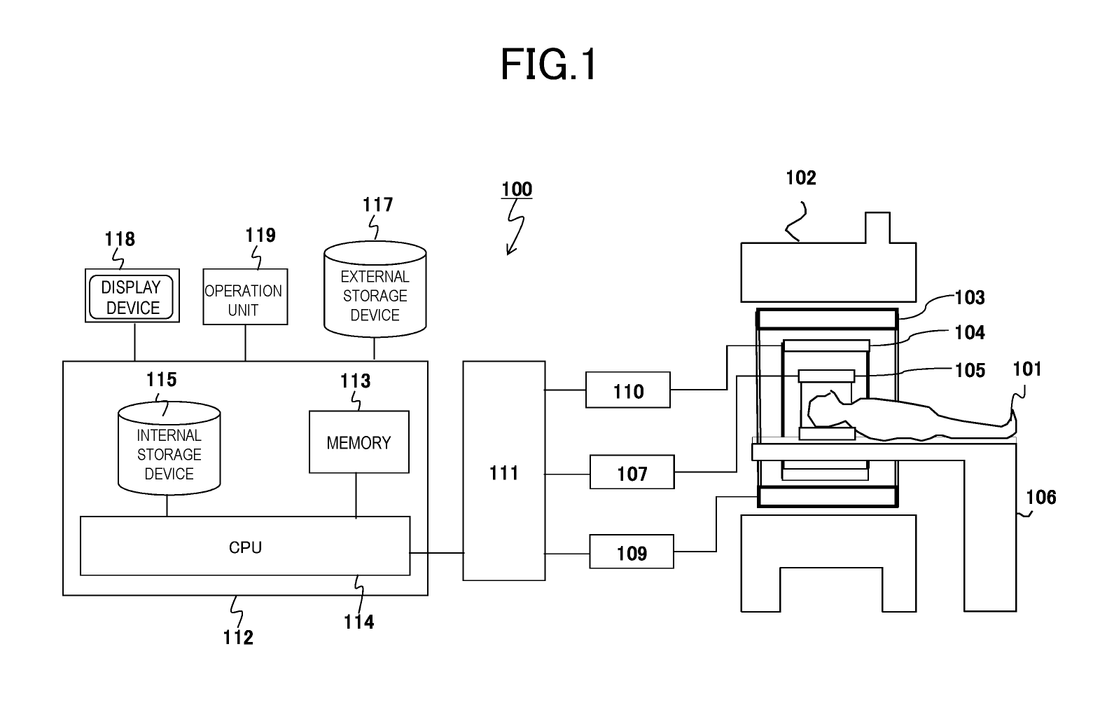

First, the MRI apparatus of the present embodiment will be described. FIG. 1 is a block diagram illustrating the overall configuration of an MRI apparatus 100 of the present embodiment. The MRI apparatus 100 of the present embodiment acquires tomographic images of an object 101 using the NMR phenomenon and comprises static magnetic field generation sources 102, gradient magnetic field coils 103 and a gradient magnetic field power source 109, high-frequency magnetic field (RF) transmission coils 104 and an RF transmission unit 110, RF reception coils 105 and a signal processing unit 107, a sequencer 111, an entire control unit 112, and a bed 106 carrying a top plate on which an object is placed in/out of the inside of the magnets, i.e. the static magnetic field generation sources 102 as illustrated in FIG. 1.

The static magnetic field generation sources 102 generate homogeneous static magnetic fields respectively in a direction orthogonal to the body axis of the object 101 in case of the vertical magnetic field method and in the body-axis direction in case of the horizontal magnetic field method. For example, static magnetic field generation magnets of the permanent magnet method, the normal conducting method, or the superconducting method are disposed around the object 101. Hereinafter, the static magnetic field direction is set as the Z-axis direction.

The gradient magnetic field coils 103 are wound in the three-axis directions X, Y, and Z that are a real space coordinate system (static coordinate system) of the MRI apparatus 100. Each of the gradient magnetic field coils 103 is connected to the gradient magnetic field power source 109 driving the coils to supply an electric current, which generates a gradient magnetic field pulse. Specifically, the gradient magnetic field power source 109 of the gradient magnetic field coils 103 is driven according to a command from the sequencer 111 to be described later and supplies an electric current to each of the gradient magnetic field coils 103. Hence, gradient magnetic field pulses Gx, Gy, and Gz are generated in the three-axis directions X, Y, and Z. The gradient magnetic field coils 103 and the gradient magnetic field power source 109 compose a gradient magnetic field generation unit.

When imaging is performed on a two-dimensional slice plane, a slice gradient magnetic field pulse (Gs) is applied in a direction orthogonal to a slice plane (imaging cross section) in order to set the slice plane for the object 101. A phase encoding gradient magnetic field pulse (Gp) and a frequency encoding (read-out) gradient magnetic field pulse (Gf) are applied in the rest of two directions that are orthogonal to the slice plane and each other, and positional information in the respective directions is encoded into nuclear magnetic resonance signals (echo signals).

The RF transmission coils 104 irradiate RF pulses to the object 101 and are connected to the RF transmission unit 110 to supply a high-frequency pulse (RF pulse) electric current. Hence, the NMR phenomenon is induced by spin of atoms composing biological tissue of the object 101. Specifically, the RF transmission unit 110 is driven according to a command from the sequencer 111 to be described later, amplitude-modulates RF pulses, and then supplies the amplified RF pulses to the RF transmission coils 104 disposed in the vicinity of the object 101, which irradiates the RF pulses to the object 101. The RF transmission coils 104 and the RF transmission unit 110 compose an RF pulse generation unit.

The RF reception coils 105 receive echo signals to be emitted by the NMR phenomenon of spin comprising biological tissue of the object 101. The RF reception coils 105 are connected to the signal processing unit 107, and the received echo signals are transmitted to the signal processing unit 107.

The signal processing unit 107 performs a detection process of the echo signals received by the RF reception coils 105. Specifically, according to the command from the sequencer 111 to be described, the signal processing unit 107 amplifies the received echo signals, divides the signals into orthogonal two-system signals by quadrature phase detection, samples each of the divided signals by the predetermined number (such as 128, 256, and 512), and then converts each of the sampled signals into a digital amount using A/D conversion. Therefore, the echo signals are acquired as time-series digital data (hereinafter, referred to as echo data) comprising the predetermined number of sampled data.

Then, the signal processing unit 107 performs various processes on the echo data and transmits the processed echo data to the sequencer 111. The RF reception coils 105 and the signal processing unit 107 compose a signal detection unit.

The sequencer 111 transmits various commands for collecting echo data required to reconstruct tomographic images of the object 101 mainly to the gradient magnetic field power source 109, the RF transmission unit 110, and the signal processing unit 107 for the control. Specifically, the sequencer 111 operates under the control of the entire control unit 112 to be described later, controls the gradient magnetic field power source 109, the RF transmission unit 110, and the signal processing unit 107 based on control data of a predetermined pulse sequence, repeatedly executes irradiation of RF pulses and application of gradient magnetic field pulses to the object 101 and detection of echo signals from the object 101, and then collects echo data required to reconstruct images for an imaging region of the object 101.

The repetition is performed by changing an application amount of phase encoding gradient magnetic field pulses in case of two-dimensional imaging and an application amount of slice encoding gradient magnetic field pulses in case of three-dimensional imaging. The number of phase encoding is normally set to a value of 128, 256, 512, or the like per image, and the number of slice encoding is normally set to a value of 16, 32, 64, or the like. Echo data from the signal processing unit 107 is output to the entire control unit 112 by these controls.

The entire control unit 112 controls the sequencer 111 and controls displaying and storing various data processes and process results. The entire control unit 112 comprises a central processing unit (CPU) 114, a memory 113, and an internal storage device 115 such as a magnetic disk. The entire control unit 112 is connected to a display device 118 and an operation unit 119 as user interfaces. An external storage device 117 such as an optical disk may also be connected.

Specifically, each part is controlled through the sequencer 111 in order to collect echo data. When the echo data is input through the sequencer 111, the central processing unit (CPU) 114 stores the echo data in a region equivalent to k-space in the memory 113 based on the encoding information applied to the echo data. Hereinafter, the description of arranging echo data in k-space means that the echo data is stored in a region equivalent to the k-space in the memory 113. The echo data group stored in the region equivalent to the k-space in the memory 113 is also referred to as k-space data.

The central processing unit (CPU) 114 executes processes such as image reconstruction and the like for the k-space data using signal processing and Fourier transform, and the resultant images of the object 101 are displayed by the display device 118, are stored in the internal storage device 115 and the external storage device 117, and are transferred to an external device through a network I/F.

The display device 118 displays the reconstructed images of the object 101. The operation unit 119 receives input of various control information of the MRI apparatus 100 and control information of processes executed by the above entire control unit 112. The operation unit 119 comprises a trackball, a mouse, a keyboard, and the like.

The operation unit 119 is disposed in the vicinity of the display device 118 so that an operator views the display device 118 to interactively control various processes of the MRI apparatus 100 through the operation unit 119.

Each function of the entire control unit 112 is realized by that the CPU 114 loads a program stored in the internal storage device 115 or the external storage device 117 into the memory 113 before the execution. It is noted that all or a part of the functions may be realized by hardware such as ASIC (Application Specific Integrated Circuit) and FPGA (Field-Programmable Gate Array). Various data to be used for processes of each function and various data to be generated during processing are stored in the internal storage device 115 or the external storage device 117.

As a clinically common nuclide, an imaging target nuclide of the MRI apparatus 100 is currently a hydrogen nucleus (proton) that is a main constituent of an object. By visualizing information about a spatial distribution of the proton density and a spatial distribution of a relaxation time in an excited state, shapes or functions of the head, abdomen, limbs, and the like of a human are imaged two- or three-dimensionally.

The present embodiment alternately executes the first imaging sequence and the second imaging sequence in which the output polarity of a component that is a generation source of at least either one of errors caused by hardware performance and signal fluctuation caused by a hardware control method in the first imaging sequence was inverted, perform addition of data acquired in each imaging sequence, and then acquires addition images. Then, each coefficient is determined so that the total of coefficients by which first data acquired in the first imaging sequence are to be multiplied is equal to the total of coefficients by which second data acquired in the second imaging sequence are to be multiplied before the addition. Hereinafter, a case of using an FSE (Fast Spin Echo) sequence as an imaging sequence will be described as an example in the present embodiment.

[FSE Sequence]

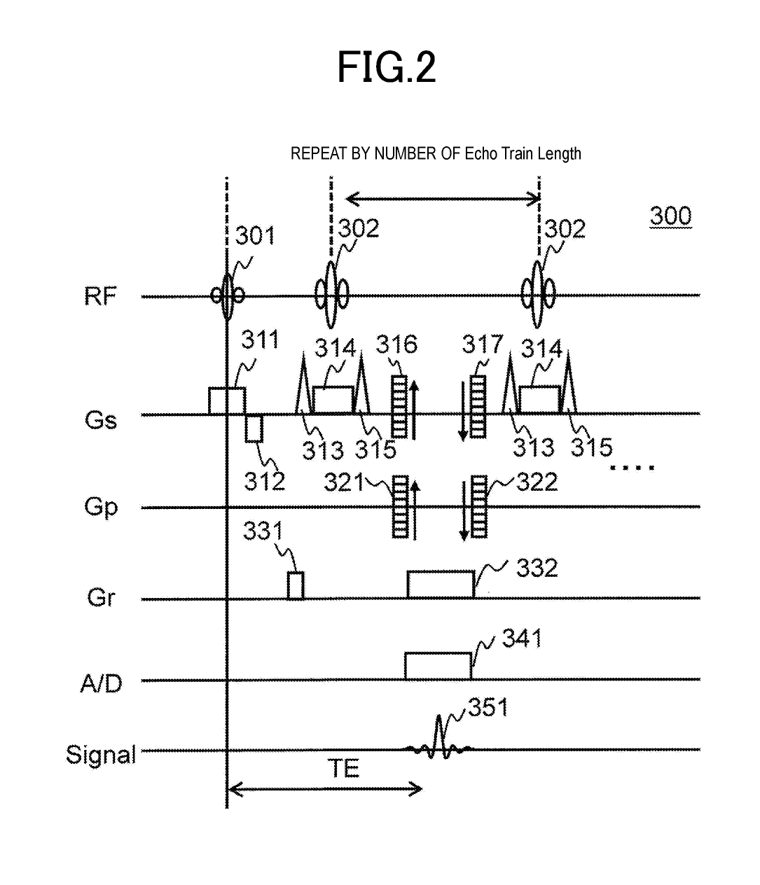

First, an FSE sequence will be described. FIG. 2 is an example of an FSE sequence 300. In the present drawing, RF, Gs, Gp, and Gr show application timings of a high-frequency magnetic field, a slice gradient magnetic field pulse, a phase encoding gradient magnetic field pulse, a frequency encoding gradient magnetic field pulse respectively, A/D shows an acquisition timing of a nuclear magnetic resonance signal (echo signal), and Signal show a generation timing of the echo signal.

As illustrated in the present drawing, first applied are an excitation RF pulse 301 providing a high-frequency magnetic field to spin in an imaging target slice plane and a slice selection gradient magnetic field pulse 311 selecting the slice in a conventional FSE sequence 300. Then, a refocus RF pulse 302 for inverting the spin in the slice plane is repeatedly applied at application intervals IET (Inter Echo Time). The number of applications (the number of repetitions) is a predetermined number of ETL (Echo Train Length).

Then, a slice selection gradient magnetic field pulse 314, a phase encoding gradient magnetic field pulse 321, and a frequency encoding gradient magnetic field pulse 332 are applied each time the refocus RF pulse 302 is applied, and an echo signal 351 is collected at a timing of a sampling window 341. In case of three-dimensional imaging, a gradient magnetic field pulse 316 (slice encoding gradient magnetic field pulse) performing encoding on the axis in the slice selection direction is applied each time the refocus RF pulse 302 is applied. The slice encoding gradient magnetic field pulse 316 may be applied in prior to the phase encoding gradient magnetic field pulse 321, and vice versa.

312 is a slice re-phase gradient magnetic field pulse for refocusing phase dispersion by the slice selection gradient magnetic field pulse 311. 313 and 315 are spoiling gradient magnetic field pulses for suppressing FID (Free Induction Decay) signals by the refocus RF pulse 302. A phase rewind gradient magnetic field pulse 322 for refocusing the phase dispersion by the phase encoding gradient magnetic field pulse 321 is applied after sampling. In case of three-dimensional imaging, a rewind gradient magnetic field pulse 317 for refocusing the phase dispersion by the slice encoding gradient magnetic field pulse 316 is applied to the axis in the slice selection direction after sampling.

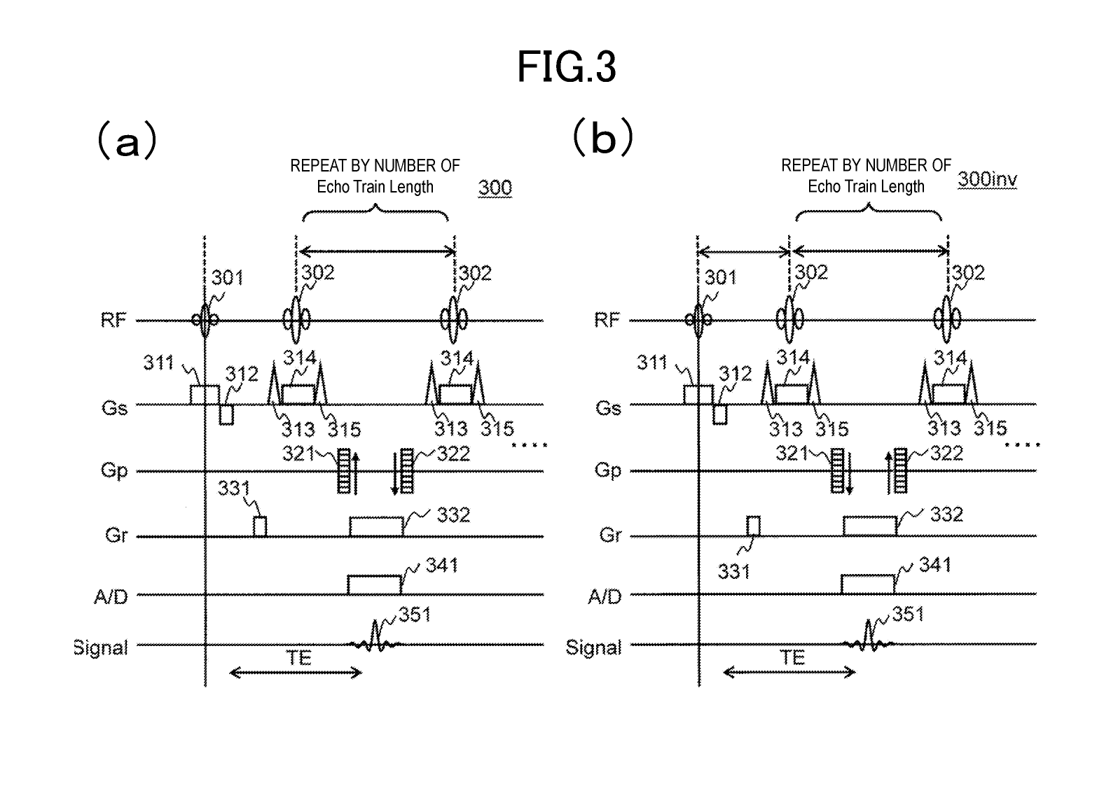

Although the FSE sequence 300 illustrated in FIG. 2 is a pulse sequence for three-dimensional imaging, a case of using the FSE sequence 300 for two-dimensional imaging is taken as an example and described below as illustrated in FIG. 3(a). That is, the description will be made using a sequence that does not include the gradient magnetic field pulse 316 and the rewind gradient magnetic field pulse 317.

The echo signal 351 collected by executing the FSE sequence 300 is arranged in a memory space (k-space). The k-space is a two-dimensional plane in which the horizontal axis is set in the frequency encoding direction and the vertical axis is set in the phase encoding direction, and, in a pulse sequence, a phase encoding amount provided for each echo signal, i.e. an intensity of a phase encoding gradient magnetic field pulse to be applied determines an arrangement order (collection order) in the ky direction of the echo signal 351 in the k-space.

The collection order of echo signals includes a centric order, a reverse centric order, a sequential order, a scroll order, and the like. The centric order is a data collection method that alternately collects echo signals in a region on the positive polarity side and in a region on the negative polarity side from around the center (ky=0) that is the low-frequency region of the k-space toward the high-frequency region side of the k-space.

The reverse centric order is a data collection method that alternately collects echo signals in a region on the positive polarity side and in a region on the negative polarity side from the high-frequency region side of the k-space toward the low-frequency region of the k-space. The sequential order is a data collection method that unidirectionally collects echo signals from one high-frequency region side toward the other high-frequency region side in the k-space. The scroll order is a data collection method that collects echo signals from around the center that is the low-frequency region of the k-space toward one high-frequency region side before collecting echo signals from the other high-frequency region side toward the low-frequency region side.

Hereinafter, a case of obtaining data filling the entire k-space by one execution of the FSE sequence 300 (one irradiation of the excitation RF pulse 301) is taken as an example and described. That is, a case where the number of ETL in the FSE sequence 300 is the number of phase encoding per image is taken as an example for the description. It is noted that the FSE sequence of the present embodiment is not limited to this and may be a sequence that acquires the k-space data capable of reconstructing one image by executing a plurality of the FSE sequences.

[How Signals are Attenuated]

In the FSE sequence 300, an intensity of the echo signals 351 to be collected each time the refocus RF pulse 302 is applied is attenuated according to a T2 value of imaging tissue as described above. Illustrated are signal intensity variation in the ky direction in k-space in a case where a point light source at a size equivalent to one pixel of a reconstructed image is disposed in the center of the field of view (FOV) for imaging and how the signal intensity varies in the y direction in an image acquired by reconstructing the k-space.

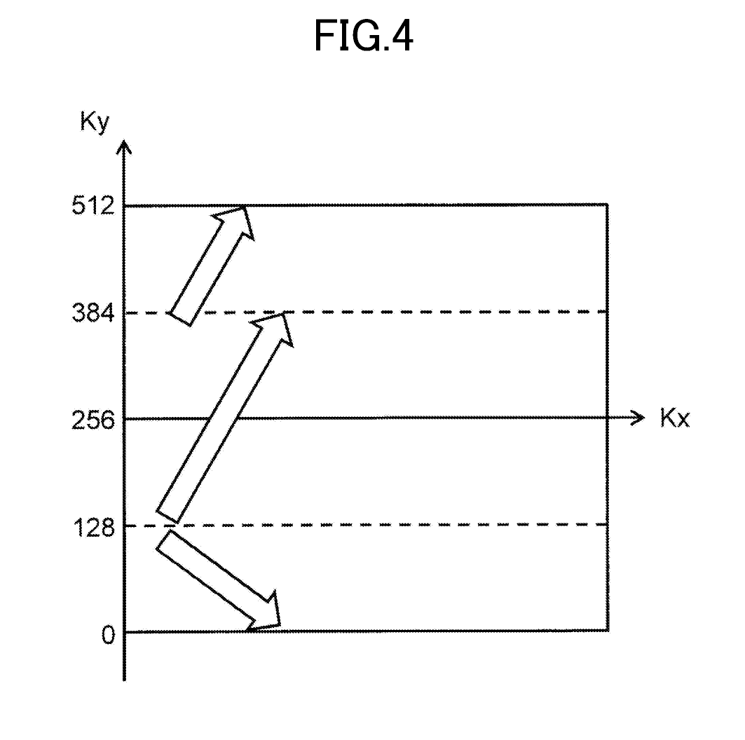

For example, an application amount (phase encoding amount) of the phase encoding gradient magnetic field pulse 321 is controlled so that echo signals are arranged in the centric order centering the position where ky is 129 as illustrated in FIG. 4. It is noted that the number of ETL is 512 here.

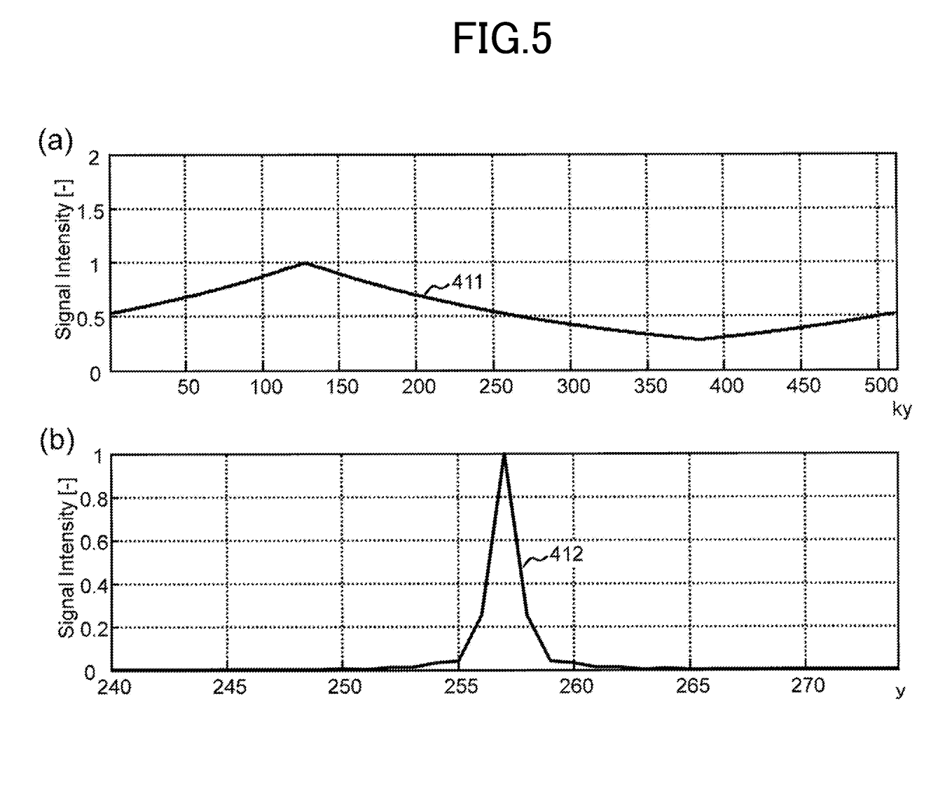

FIG. 5(a) illustrates a variation state of the echo signal intensity (profile) 411 in the ky direction in k-space. In the present drawing, the horizontal axis is ky (phase encoding amount), and the vertical axis is a signal intensity. Thus, the signal intensity reaches the maximum value in the position where ky is 129 and varies according to the T2 attenuation.

FIG. 5(b) illustrates a variation state of the echo (profile) 412 in the y direction of an image acquired by reconstructing the above k-space data. In the present drawing, the horizontal axis is a pixel position in the y-axis direction of an image, and the vertical axis is a signal intensity.

As illustrated in FIG. 5(b), a point light source is originally a size of one pixel but has a predetermined width in case of an image acquired from k-space data having signal intensity fluctuation in the ky direction illustrated in FIG. 5(a). That is, this affects adjacent pixel values and results in a blurred state.

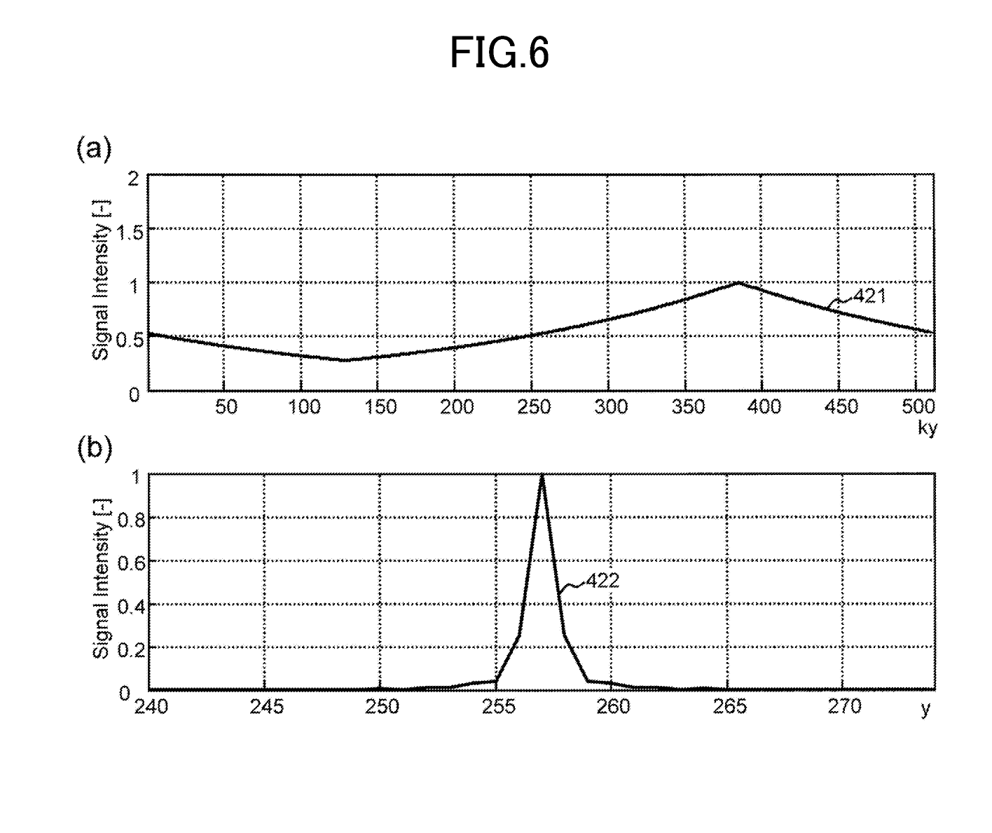

Here, FIGS. 6(a) and 6(b) illustrates the states of a profile 421 in the ky direction of k-space and a profile 422 in the y direction of an image in case of imaging the same point light source in an FSE sequence 300inv in which the way of providing a phase encoding amount was inverted in the FSE sequence 300 of FIG. 3(a) as illustrated in FIG. 3(b). The vertical and horizontal axes are similar to FIGS. 5(a) and 5(b) respectively.

As illustrated in these drawings, how the profile 421 of the k-space varies is inverted compared to when the FSE sequence 300 illustrated in FIG. 5(a) is executed. The profile of the image gets wide and results in a blurred image despite the fact that the imaging target is a point light source similarly to FIG. 5(b).

[Addition Imaging]

In addition imaging using a conventional FSE sequence, the FSE sequence 300 and the FSE sequence 300inv in which the way of providing a phase encoding amount of the FSE sequence 300 was inverted are alternately executed by the same number, and the results are added. Forexample, the FSE sequence 300 is executed at odd-numbered times, and the FSE sequence 300inv is executed at even-numbered times.

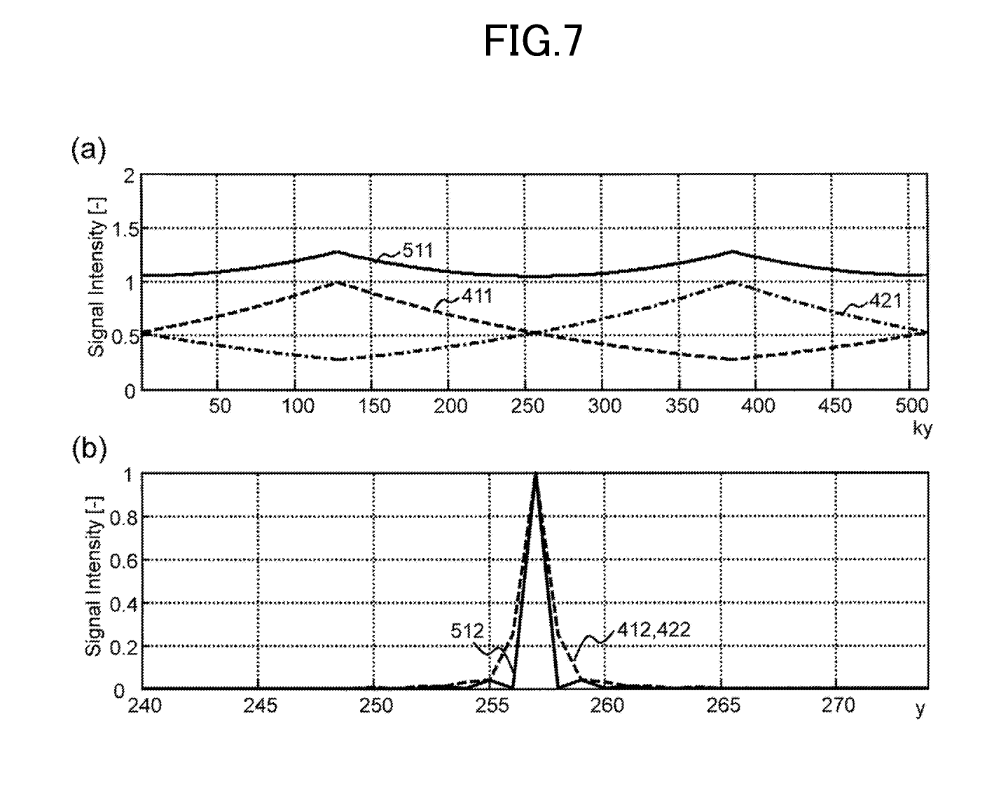

FIG. 7(a) illustrates a profile 511 in the ky direction of k-space (added k-space) when k-space data is added after executing the FSE sequence 300 at the first time and the FSE sequence 300inv at the second time. FIG. 7(b) also illustrates a profile 512 in the y direction of an image (addition image) reconstructed from the added k-space. The vertical and horizontal axes are similar to FIGS. 5(a) and 5(b) respectively.

By adding both the k-space data, the profile 511 pf the added k-space is more moderate than variations of the profiles 411 and 421 of the respective k-spaces. In the profile 512 of the addition image, the width of a point light source is significantly improved compared to the profile 412 of the image at the first time and the profile 422 of the image at the second time. That is, this does not affect the other pixels, and an image blur is improved.

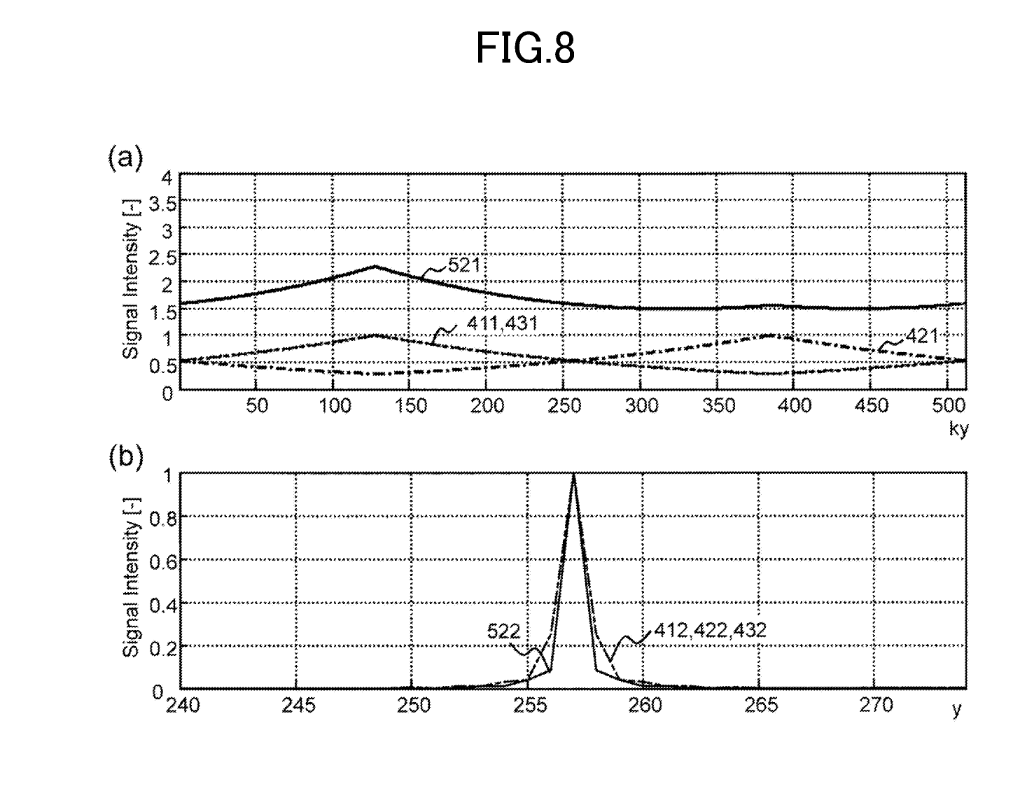

Here, FIGS. 8(a) and 8(b) illustrate the addition results in a case where the number of measurements is an odd-numbered time (three times). That is, at the time when the FSE sequence 300 is executed at the third time and the first, second, and third measurement results are added, FIG. 8(a) illustrates the profile 521 in the ky direction of the added k-space, and FIG. 8(b) illustrates the profile 522 in the y direction of the addition image. The vertical and horizontal axes are similar to FIGS. 5(a) and 5(b) respectively.

As illustrated in FIGS. 8(a) and 8(b), in a case where an imaging sequence is executed for an odd-numbered time, i.e. a case where the execution times are not the same between the FSE sequence 300 and the FSE sequence 300inv, the signal intensity variation is not sufficiently suppressed in the added k-space, which increase the width of the profile 522 of the aaddition image.

Thus, in a conventional addition imaging, an effect of T2 attenuation remains in the addition image unless the FSE sequence 300 and the FSE sequence 300inv are executed at the same time.

In the present embodiment, data acquired in the FSE sequence 300inv is multiplied by a coefficient during the addition, and the total of signal intensities of data acquired in the FSE sequence 300 and the total of signal intensities of data acquired in the FSE sequence 300inv are set approximately equal to each other.

[Configuration of Entire Control Unit]

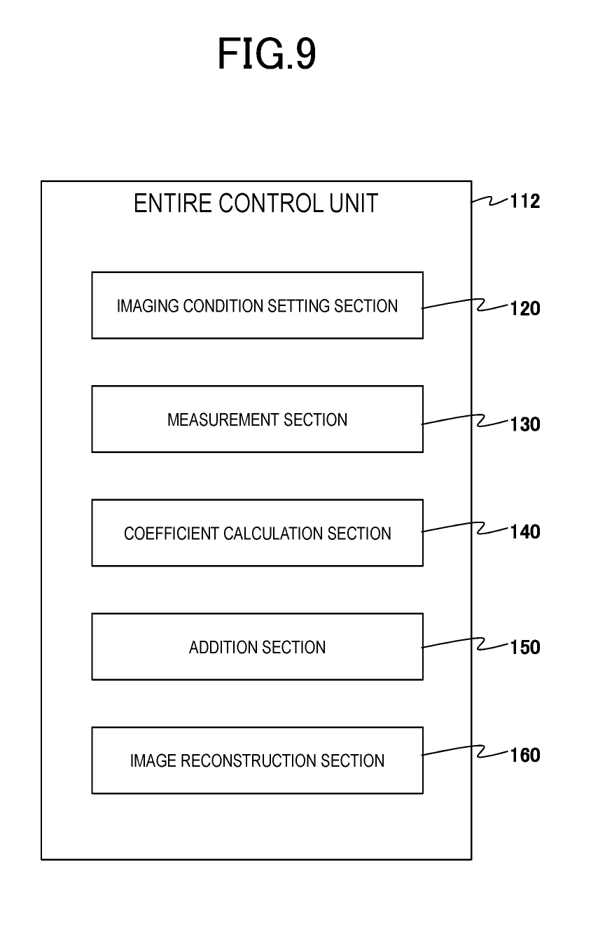

In order to realize the configuration, the entire control unit 112 of the present embodiment comprises an imaging condition setting section 120, a measurement section 130, a coefficient calculation section 140, an addition section 150, and an image reconstruction section 160 as illustrated in FIG. 9.

The imaging condition setting section 120 receives imaging conditions from a user through the operation unit 119 and/or the display device 118. The present embodiment performs addition imaging. Therefore, the imaging conditions to be received include the total execution number of imaging sequences (the total number of additions) NEX. It is noted that NEX is an integer equal to or more than 2.

The measurement section 130 executes measurement according to a predetermined pulse sequence by the total number of additions NEX. The present embodiment executes a first imaging sequence and a second imaging sequence in order to acquire first data and second data respectively. The second imaging sequence is a sequence in which the polarity of a predetermined gradient magnetic field pulse was inverted from among a plurality of gradient magnetic field pulses composing the first imaging sequence. The gradient magnetic field pulse whose polarity is to be inverted is a gradient magnetic field pulse that can generate at least either of errors caused by hardware performance or signal fluctuation caused by a hardware control method.

In the present embodiment, the first sequence is set as the FSE sequence 300, and the second sequence is set as the FSE sequence 300inv. As described above, the FSE sequence 300inv is a sequence in which the way of providing a phase encoding amount of the FSE sequence 300 was inverted. That is, in the second imaging sequence, the gradient magnetic field pulse whose polarity is to be inverted is a phase encoding gradient magnetic field pulse.

The measurement section 130 alternately executes both of the FSE sequence 300 and the FSE sequence 300inv by the total number of additions NEX received by the imaging condition setting section 120.

The coefficient calculation section 140 calculates a second weight coefficient by which the second data are to be multiplied during the addition. At this time, the second weight coefficient is calculated so that the total of the second weight coefficients by which the second data to be added are to be multiplied is equal to the total of first weight coefficients by which the first data to be added are to be multiplied.

In the present embodiment, the coefficient calculation section 140 calculates the second weight coefficient so that the total of coefficients (first weight coefficients) by which k-space data acquired in the FSE sequence 300 are to be multiplied is equal to the total of coefficients (second weight coefficients) by which k-space data acquired in the FSE sequence 300inv are to be multiplied.

The total number of additions NEX is used for calculating the coefficients. For example, the coefficient calculation section 140 calculates a second weight coefficient according to the following equation (1) by setting a first weight coefficient to 1.

$$C 2 = \frac{( NEX - INT ( \frac{NEX}{2} ) )}{INT ( \frac{NEX}{2} )} \qquad ( 1 )$$

Here, Int(x) is a calculation of rounding up digits after the decimal point of x in order to obtain an integer.

The addition section 150 adds the first data multiplied by a first weight coefficient to the second data multiplied by the second weight coefficient in order to acquire addition data. When Sn (n is an integer equal to or more than 1) is a signal intensity of echo signals acquired by executing the n-th imaging sequence, the addition data (additional k-space data) S is acquired according to the following equation (2) in a case where the total number of additions NEX is an odd number or according to the following equation (3) in a case where the total number of additions NEX is an even number in the present embodiment.

S=C1·S₁+C2·S₂+C1·S₃+C2·S₄+ . . . +C1·S_{NEX} (2)

S=C1·S₁+C2·S₂+C1·S₃+C2·S₄+ . . . +C2·S_{NEX} (3)

The image reconstruction section 160 reconstructs images from k-space data using a Fourier transform or the like.

The present embodiment reconstructs addition images from addition data (additional k-space data S).

[Process Flow]

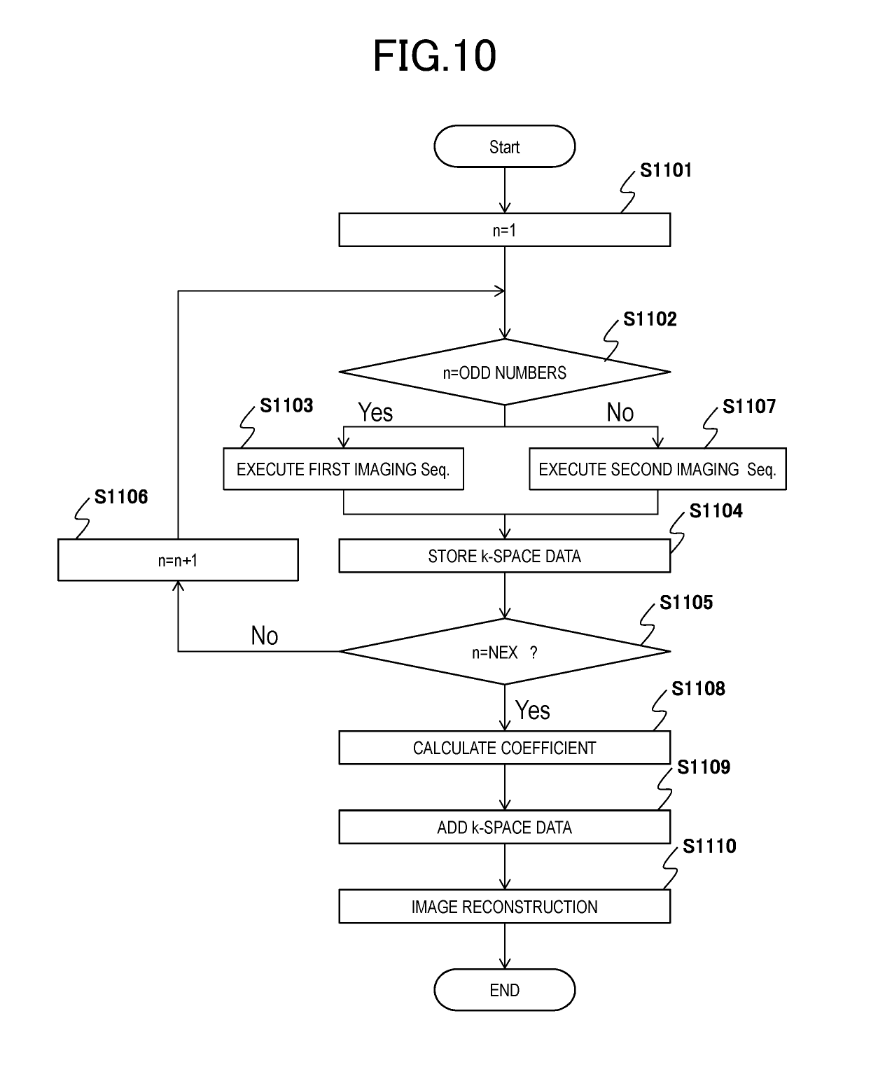

FIG. 10 illustrates a process flow of addition imaging by the entire control unit 112 of the present embodiment. The process of addition imaging starts after receiving a setting for the total number of additions NEX as an imaging condition from a user and receiving an imaging start command.

First, the measurement section 130 initializes a counter n (n=1) that counts the number of measurements, i.e. the number of imaging sequences (the FSE sequence 300 or the FSE sequence 300inv) (Step S1101).

Then, the measurement section 130 determines whether n is odd or even (Step S1102) and executes the FSE sequence 300 as the first imaging sequence (FIRST IMAGING Seq.) in a case where n is odd (Step S1103). Then, the acquired echo signal 351 is disposed in k-spaces generated in the memory 113 by associating with n (k-space data storage: Step S1104). The k-spaces are generated by the number of NEX by associating with the counter n in the present embodiment. It is noted that k-space data acquired by executing the first imaging sequence is referred to as first k-space data.

On the other hand, in a case where n is even, the measurement section 130 executes the FSE sequence 300inv as the second imaging sequence (SECOND IMAGING Seq.) (Step S1107). Then, the procedure proceeds to Step S1104. It is noted that k-space data acquired by executing the second imaging sequence is referred to as second k-space data.

The measurement section 130 repeats the above processes by the total number of additions NEX specified by the imaging condition until the imaging sequence is executed (Steps S1105 and S1106).

After the imaging sequence is executed by the number of NEX, the coefficient calculation section 140 calculates a second weight coefficient C2 according to, for example, the above equation (1) using the total number of additions NEX (Step S1108).

The addition section 150 adds all the first k-space data to all the second data multiplied by the second weight coefficient C2 calculated respectively in order to acquire additional k-space data (Step S1109). Then, the image reconstruction section 160 reconstructs addition images from the additional k-space data (Step S1110).

It is noted that the coefficient calculation process by the coefficient calculation section 140 is not limited to the above timing. The coefficient calculation process may be performed at any time until k-space data is added after a user sets the total number of additions NEX as an imaging condition.

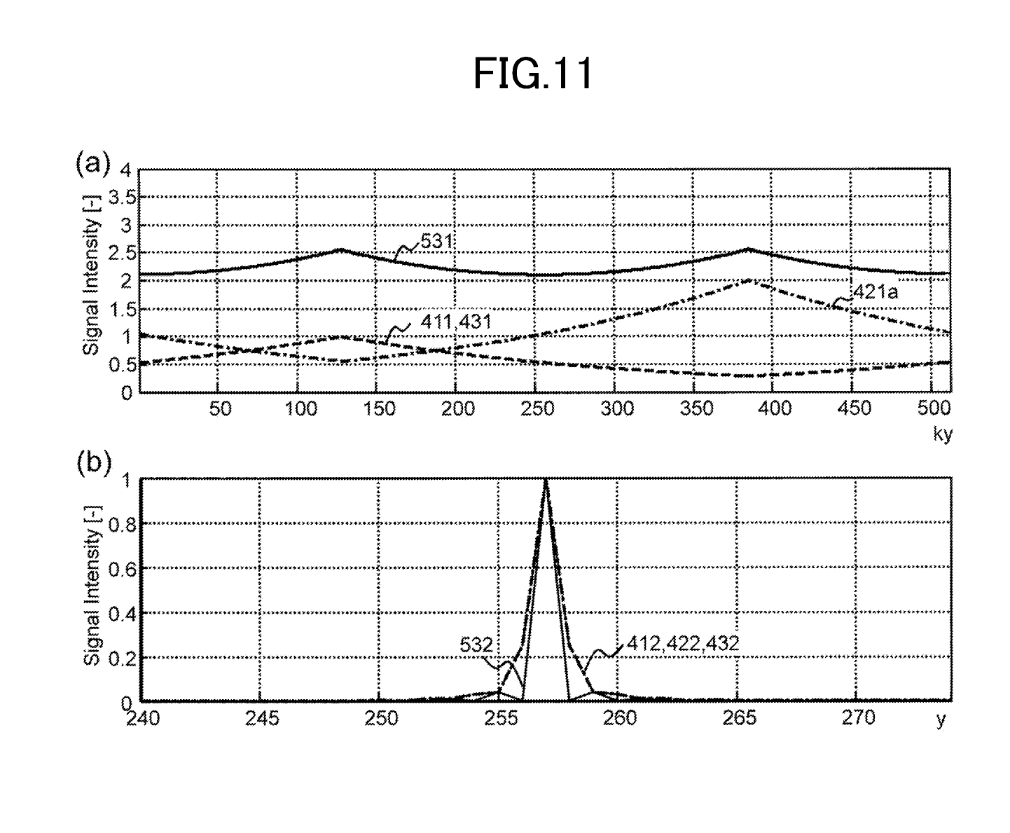

In a case where the total number of additions NEX is 3 as illustrated in the above FIGS. 8(a) and 8(b), FIG. 11(a) illustrates a profile 531 of k-space after addition processing of the present embodiment, and FIG. 11(b) illustrates a profile 532 of an image reconstructed from the k-space. The vertical and horizontal axes are the same as FIGS. 5(a) and 5(b) respectively. A profile 421a is k-space data, which was acquired by executing the second imaging sequence, multiplied by the second weight coefficient C2

As illustrated in FIG. 11(b), the profile 532 of the image reconstructed from the k-space data added using the method of the present embodiment shows that the point light source has a smaller width and that an image blur is improved similarly in a case where the FSE sequence 300 and the FSE sequence 300inv are executed by the same number of times using the conventional method illustrated in FIG. 7(b).

That is, as illustrated in FIG. 11(b), the second weight coefficient is calculated using the method of the present embodiment and are multiplied to k-space data acquired in the FSE sequence 300inv before adding, which shows that a blur of the point light source is improved.

As described above, the MRI apparatus 100 of the present embodiment comprises the measurement section 130 that executes the first and second imaging sequences in order to acquire the first and second data respectively, the coefficient calculation section 140 that calculates the second weight coefficient C2 by which the second data are to be multiplied, and the addition section 150 adds the first data multiplied by a first weight coefficientCl to the second data multiplied by the second weight coefficient C2 in order to acquire addition data, the second imaging sequence is an imaging sequence in which the polarity of a predetermined gradient magnetic field pulse was inverted from among a plurality of gradient magnetic field pulses composing the first imaging sequence, and the coefficient calculation section 140 calculates the second weight coefficient C2 so that the total of the second weight coefficients C2 is equal to the total of the first weight coefficients C1. It is desirable that the gradient magnetic field pulse whose polarity is to be inverted is a gradient magnetic field pulse generating at least either of errors caused by hardware performance or signal fluctuation caused by a hardware control method.

The first imaging sequence is the FSE (Fast Spin Echo) sequence 300, and the gradient magnetic field pulse whose polarity is to be inverted may include the phase encoding gradient magnetic field pulse 321.

Also, the first and second data may also be k-space data respectively.

The first weight coefficient C1 may be set also to 1. Additionally, in case of a plurality of the second data, all the second weight coefficients by which the respective second data to be multiplied may be equal.

Thus, the second weight coefficient C2 is determined to be multiplied to the second k-space data according to the total number of additions NEX set as an imaging condition by a user in the present embodiment. The second weight coefficient C2 is determined so that the total of the first weight coefficients C1 are equal to the total of the second weight coefficients C2.

Hence, the total of signal intensities of the first k-space data is approximately equal to the total of signal intensities of the second k-space data multiplied by the second weight coefficient, and, by adding both the signals intensities, signal intensity fluctuation due to T2 attenuation are appropriately offset.

Therefore, according to the present embodiment, high-quality images can be acquired regardless of the total number of additions. Therefore, imaging can be executed by the optimal number of additions determined under the imaging condition, which can acquire desired-quality images within a desired time.

<Modification of Coefficient Multiplication and Additional Target>

Although the present embodiment performs addition after multiplying k-space data by a coefficient and reconstructs images using the added k-space data in addition imaging, the image reconstruction is not limited to this. The image reconstruction may be performed so that each of k-space data is reconstructed to acquire images whose pixel values are complex numbers and the images are multiplied by each coefficient before addition.

In this case, images are reconstructed each time k-space data required to reconstruct one image is acquired in the measurement section 130. That is, the first and second data acquired by the measurement section 130 is reconstructed images respectively.

<Modification of Coefficient>

In the present embodiment, all the first weight coefficients C1 by which the first data are to be multiplied are set to 1, and all the second weight coefficients C2 by which each of the second data is to be multiplied are the same in a case of a plurality of the second data, i.e. a case where the total number of additions NEX is equal to or more than 3.

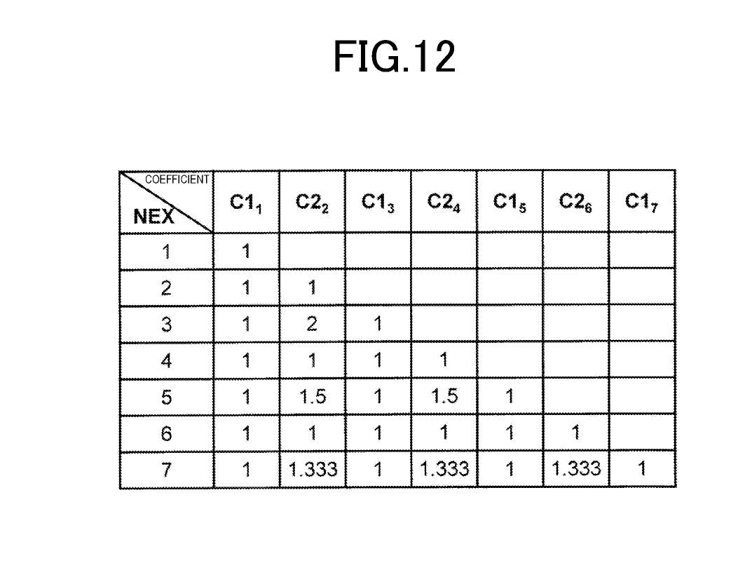

As an example, FIG. 12 indicates the second weight coefficients C2 to be calculated according to the above equation (1) by the coefficient calculation section 140 of the present embodiment in a case where the total number of additions NEX is 1 to 7. Here, C1ₙ indicates a first weight coefficient by which k-space data acquired by executing the n-th first imaging sequence (FSE sequence 300) is to be multiplied, and C2ₙ indicates a second weight coefficient by which k-space data acquired by executing the n-th second imaging sequence (FSE sequence 300inv) is to be multiplied.

However, coefficients to be calculated by the coefficient calculation section 140 are not limited to this in a case where the total of the first weight coefficients C1 by which the first k-space data are to be multiplied is equal to the total of the second weight coefficients C2 by which the second k-space data are to be multiplied. That is, for example, in a case where the total number of additions NEX is 7, only C2₂ is set to 2, and all the other coefficients may be set to 1. The first weight coefficients do not need to be set to 1.

Additionally, the second weight coefficients C2 are calculated according to the total number of additions NEX set as an imaging condition by a user in the present embodiment. The above equation (1) is used for the calculation for example. INT(NEX/2) indicates the number of the second data in the equation (1). (NEX-INT(NEX/2) is the number of the first data. Therefore, in a case where the first weight coefficients C1 are set to 1, the total of the second weight coefficients C2 is equal to the number of the first data to be added.

Therefore, in a case where he first weight coefficients C1 are set to 1, i.e. a case where the first data is not multiplied by any coefficient, the coefficient calculation section 140 calculates the number of the first data from the total number of additions NEX, and the second weight coefficients C2 may be calculated so that the total is equal to the number of the first data to be added.

<Modification of Imaging Sequence>

In the present embodiment, although a case of using the two-dimensional FSE sequence 300 as an imaging sequence is taken as an example for the description, the imaging sequence is not limited to this. The imaging sequence may be a three-dimensional FSE sequence.

Additionally, a case of using an FSE sequence as an imaging sequence is taken as an example for the description in the present embodiment. However, the imaging sequence to be used is not limited to this and may be an EPI sequence for example.

[EPI Sequence]

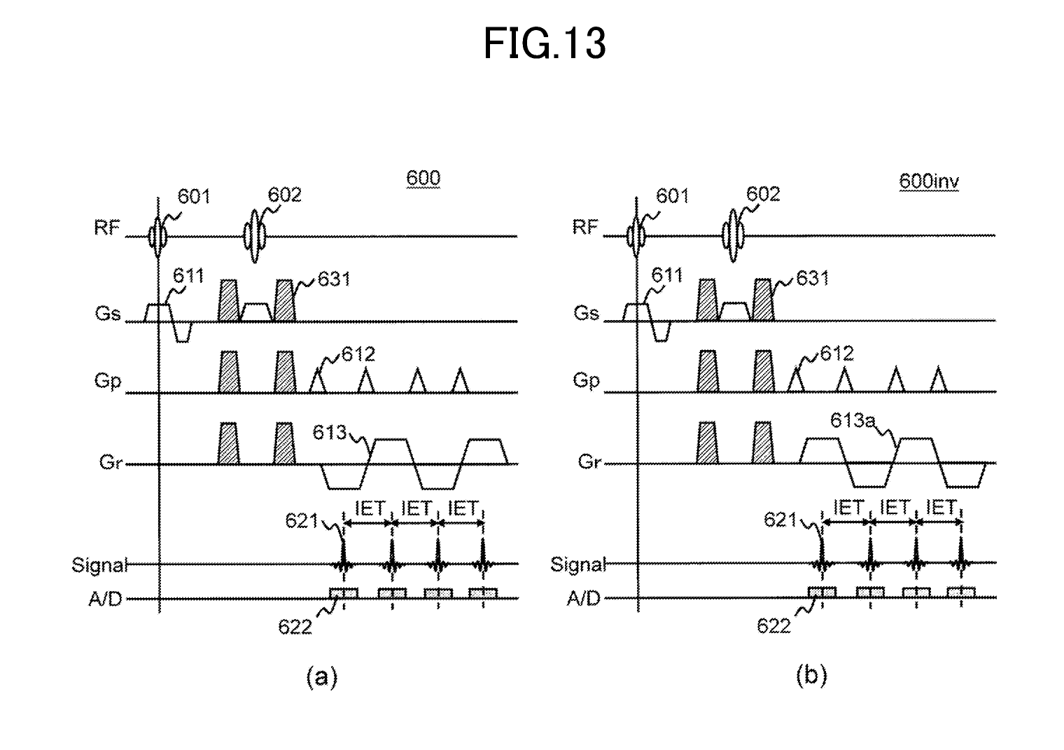

FIG. 13(a) is an example of an EPI sequence 600. As illustrated in the present drawing, the EPI sequence 600 collects all the echo signals required to fill k-space by inverting gradient magnetic field pulses at a high speed after excitation by one excitation pulse (90-degree pulse).

Specifically, an inversion pulse (180-degree pulse) 602 is applied after a slice selection gradient magnetic field pulse 611 and an excitation pulse (90-degree pulse) are applied. Then, sampling windows 622 are set at IET intervals in order to collect echo signals 621 while blip gradient magnetic field pulses 612 and readout (frequency encoding) gradient magnetic field pulses 613 are repeatedly applied.

It is noted that gradient magnetic field pulses referred to as MPG (Motion Probing Gradient) pulses 631 are applied before and after the 180-degree pulse 602 in case of using the EPI sequence 600 for diffusion-weighted imaging.

The EPI sequence 600 includes a single-shot sequence and a multi-shot sequence. Data filling the entire k-space is acquired by setting “Repetition Unit” between the excitation pulse 601 and the next excitation pulse 601 to be applied to once in case of the single-shot sequence and by repeating “Repetition Unit” by a plurality of times in case of the multi-shot sequence.

In a measurement (EPI measurement) that uses the EPI sequence 600, the measurement is performed while the polarity of the readout gradient magnetic field pulses 613 is being inverted alternately. The EPI sequence 600inv in this case is illustrated in FIG. 13(b). 613a are readout gradient magnetic field pulses whose polarities were inverted. Hence, phase differences occur between the echo signals 621, which can generate N/2 artifacts.

In the EPI measurement, as described in PTL 2, measurements filling the entire k-space are repeated a plurality of times (even-numbered times) in order to suppress the artifacts. At this time, the measurements is executed by inverting the polarities of the readout gradient magnetic field pulses 613 between odd-numbered times and even-numbered times, both are added, and then images are reconstructed from the added result. Alternatively, the images are reconstructed for each measurement, and then the reconstructed images are added.

The total number of additions NEX is set to 2. A pixel value M₁ acquired in the first measurement and a pixel value M₂ acquired in the second measurement are represented in the following equations (4) and (5) respectively.

$$\begin{matrix}{M}_{1} = \frac{1}{2} \cdot M ( x , y ) ( 1 + exp ( i θ ( x , y ) ) ) + \frac{1}{2} \cdot M ( x , y \pm \frac{FOV}{2} ) ( 1 - exp ( i θ ( x , y \pm \frac{FOV}{2} ) ) ) & ( 4 ) \\ {M}_{2} = \frac{1}{2} \cdot M ( x , y ) ( 1 + exp ( i θ ( x , y ) ) ) + \frac{1}{2} \cdot M ( x , y \pm \frac{FOV}{2} ) ( - 1 + exp ( i θ ( x , y \pm \frac{FOV}{2} ) ) ) & ( 5 )\end{matrix}$$

The term M(x,y±FOV/2) is equivalent to an N/2 artifact component imaged in a half-shifted position in the FOV.

The result M₁₊₂ in which these were added is represented in the following equation (6):

M₁₊₂=M₁+M₂=M(x,y)(1+exp(iθ(x,y))) (6)

The added result is as the equation (6), the term M(x,y±FOV/2) is removed, and then the N/2 artifact component disappears. However, also in this case, used is an algorithm limited to a case where the total number of additions NEX is set to an even-numbered time similarly to a case of addition imaging using an FSE sequence.

For example, in a case where the total number of additions NEX is set to 3, A pixel value M₁ of an image acquired in the first measurement and a pixel value M₂ of the second measurement are represented in the above equations (4) and (5) respectively, and a pixel value M₃ of the third measurement is represented in the following equation (7).

$${M}_{3} = \frac{1}{2} \cdot M ( x , y ) ( 1 + exp ( i θ ( x , y ) ) ) + \frac{1}{2} \cdot M ( x , y \pm \frac{FOV}{2} ) ( 1 - exp ( i θ ( x , y \pm \frac{FOV}{2} ) ) ) \qquad ( 7 )$$

Therefore, a result M₁₊₂₊₃ in a case where pixel values of each measurement are added as is similarly to the conventional method is represented in the following equation (8), and the N/2 artifacts remain.

$$\begin{matrix}{M}_{1 + 2 + 3} = {M}_{1} + {M}_{2} + {M}_{3} \\ = \frac{3}{2} \cdot M ( x , y ) ( 1 + exp ( i θ ( x , y ) ) ) + \frac{1}{2} \cdot \\ M ( x , y \pm \frac{FOV}{2} ) ( 1 - exp ( i θ ( x , y \pm \frac{FOV}{2} ) ) )\end{matrix} \qquad ( 8 )$$

Here, the method of the above embodiment is applied by setting the EPI sequence 600 as the first imaging sequence and the EPI sequence 600inv in which the readout gradient magnetic field pulses 613 of the EPI sequence 600 was inverted as the second imaging sequence.

That is, the measurement section 130 alternately executes the first imaging sequence (EPI sequence 600) and the second imaging sequence (EPI sequence 600inv). The coefficient calculation section 140 also uses the total number of additions NEX set as an imaging condition in order to calculate the second weight coefficient C2 by which the second data acquired in the second imaging sequence is to be multiplied according to the above equation (1). Then, the addition section 150 adds all the acquired first and second data while multiplying the second weight coefficient C2 by the second data.

For example, in a case where the total number of additions NEX is 3, the following equation (9) represents a result M₁₊₂₊₃ in which M₂ that is the second data is multiplied by 2 as the second weight coefficient C2 calculated using the above method of the present embodiment before addition.

M₁₊₂₊₃=M₁+2·M₂+M₃=2·M(x,y)(1+exp(iθ(x,y))) (9)

Thus, the term M(x,y±FOV/2) is removed, and then the N/2 artifact component disappears. That is, according to the present embodiment, the N/2 artifacts can be suppressed regardless of the total number of additions NEX even by the addition measurement in which an imaging sequence is set as an EPI sequence.

<Other Modification>

Additionally, the first embodiment may be applied also to parallel imaging. That is, the method of the first embodiment is applied as an imaging sequence to be added m times in parallel imaging at an m-fold (m is an odd number equal to or more than 3) speed.

Even when the parallel imaging at an m-fold speed is performed for m times, an imaging time is the same as a case where total number of additions is 1. In addition to this, in the parallel imaging, an echo train length is shortened, and an auxiliary image-quality improvement effect can be expected to an image blur. Therefore, higher-quality images can be acquired within the same measurement time by applying the parallel imaging to the present embedment.

### Second Embodiment

Next, the second embodiment of the present invention will be described. In the present embodiment, a user selects images to be used for addition from among images acquired by the total number of additions NEX set as an imaging condition. For example, a user excludes images considerably deteriorated due to the body motion or the like. In the first embodiment, the total number of additions NEX is determined as the imaging condition, and the number of k-space data or images to be added actually is already known. However, in the present embodiment, the number of images to be added actually is not determined.

The MRI apparatus 100 of the present embodiment basically has the similar configuration to the first embodiment. However, the number of images to be added, the configuration of the entire control unit 112 is different.

[Functional Block of Entire Control Unit]

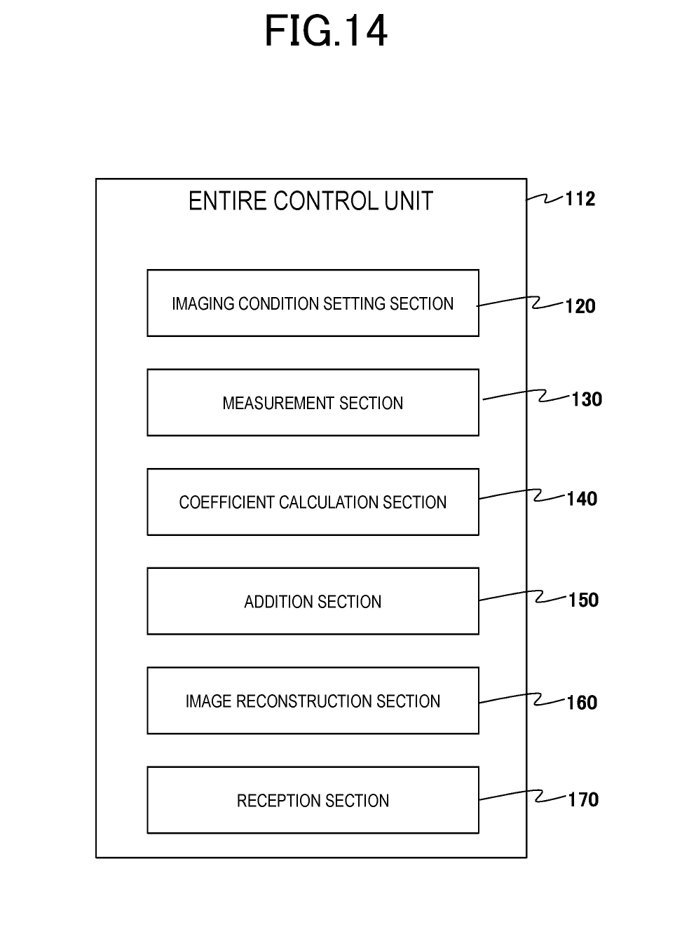

The entire control unit 112 of the present embodiment comprises a reception section 170 in addition to the imaging condition setting section 120, the measurement section 130, the coefficient calculation section 140, the addition section 150, and the image reconstruction section 160 similarly to the first embodiment as illustrated in FIG. 14.

The functions of the imaging condition setting section 120, the measurement section 130, and the image reconstruction section 160 are equivalent to the same functions of the first embodiment. That is, in the present embodiment, the measurement section 130 alternately executes the first imaging sequence and the second imaging sequence, the image reconstruction section 160 reconstructs images from k-space data acquired in the first imaging sequence and k-space data acquired in the second imaging sequence respectively. Hereinafter, the images reconstructed from k-space data acquired in the first imaging sequence are referred to as the first images, and the images reconstructed from k-space data acquired in the second imaging sequence are referred to as the second images.

The reception section 170 presents the first data (i.e. the first images) and the second data (i.e. the second images) to a user and receives a choice of adoption or rejection. That is, the reception section 170 respectively presents the first and second images by the total number of additions NEX to the user and receives a determination of whether or not to use the images for addition from the user. For example, a screen for receiving adoption or rejection is displayed on the display device 118, and the adoption or rejection of each image is received through the screen.

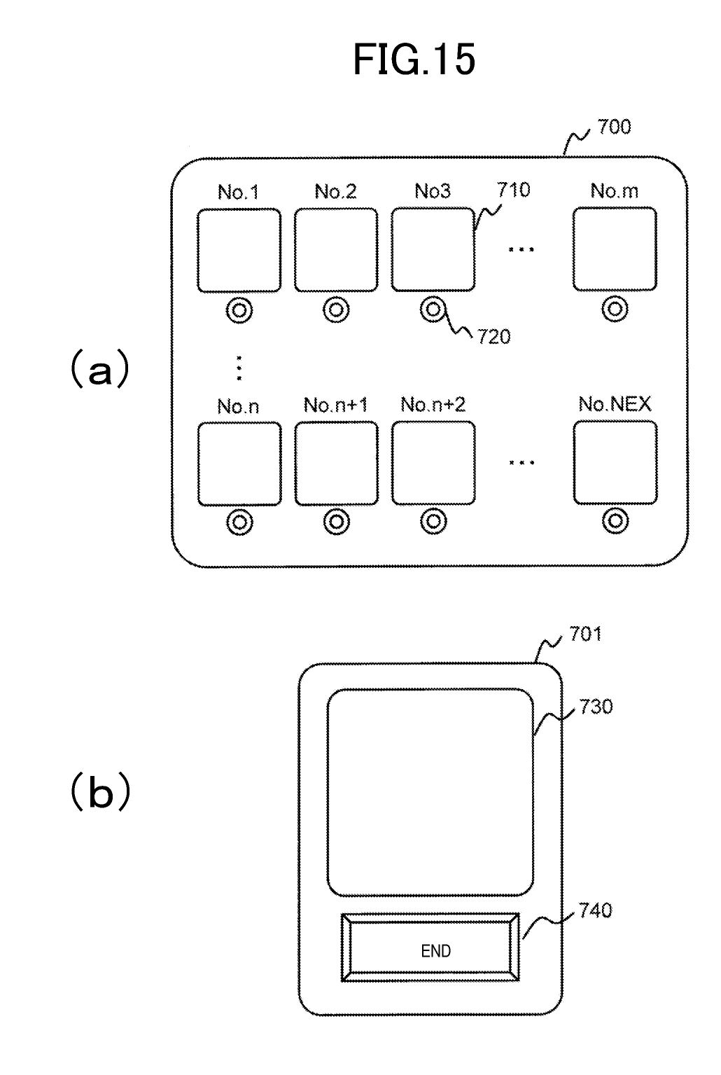

FIG. 15(a) illustrates an example of an adoption/rejection receiving screen 700. As illustrated in the present drawing, the adoption/rejection receiving screen 700 comprises image display regions 710 and adoption/rejection receiving regions 720. For example, the image display regions 710 displays acquired first and second images. The adoption/rejection receiving regions 720 are provided for each image and receive adoption or rejection for each image. For example, the adoption/rejection receiving regions 720 may be configured so that radio buttons are provided as illustrated in the present drawing in order to select images to be adopted only or images not to be adopted only.

The reception section 170 obtains the number of the respective first and second images to be adopted and received through the adoption/rejection receiving screen 700 (the total number of the first images N1 and the total number of the second images N2) and notifies the coefficient calculation section 140 of the number.

The coefficient calculation section 140 calculates a second weight coefficient C2 that is a weight coefficient to be provided for the second images using the total number of the first images N1 and the total number of the second images N2 adopted through the reception section 170. The description will be made by taking a case where the first weight coefficient C1 by which the first images is to be multiplied is 1 as an example also in the present embodiment. Similarly to the first embodiment, the second weight coefficient C2 is calculated so that the total of the first weight coefficients C1 to be multiplied by the adopted first data (i.e. the first images) is equal to the total of the second weight coefficients C2 by which the adopted second data (i.e. the second images) are to be multiplied.

For example, the coefficient calculation section 140 calculates the second weight coefficient C2 according to the following equation (10).

C2=N1/N2 (10)

The addition section 150 of the present embodiment adds. the adopted second data (i.e. the second images), by which the second weight coefficients C2 are to be multiplied, to the adopted first data (i.e. the first images) in order to obtain addition images.

[Process Flow]

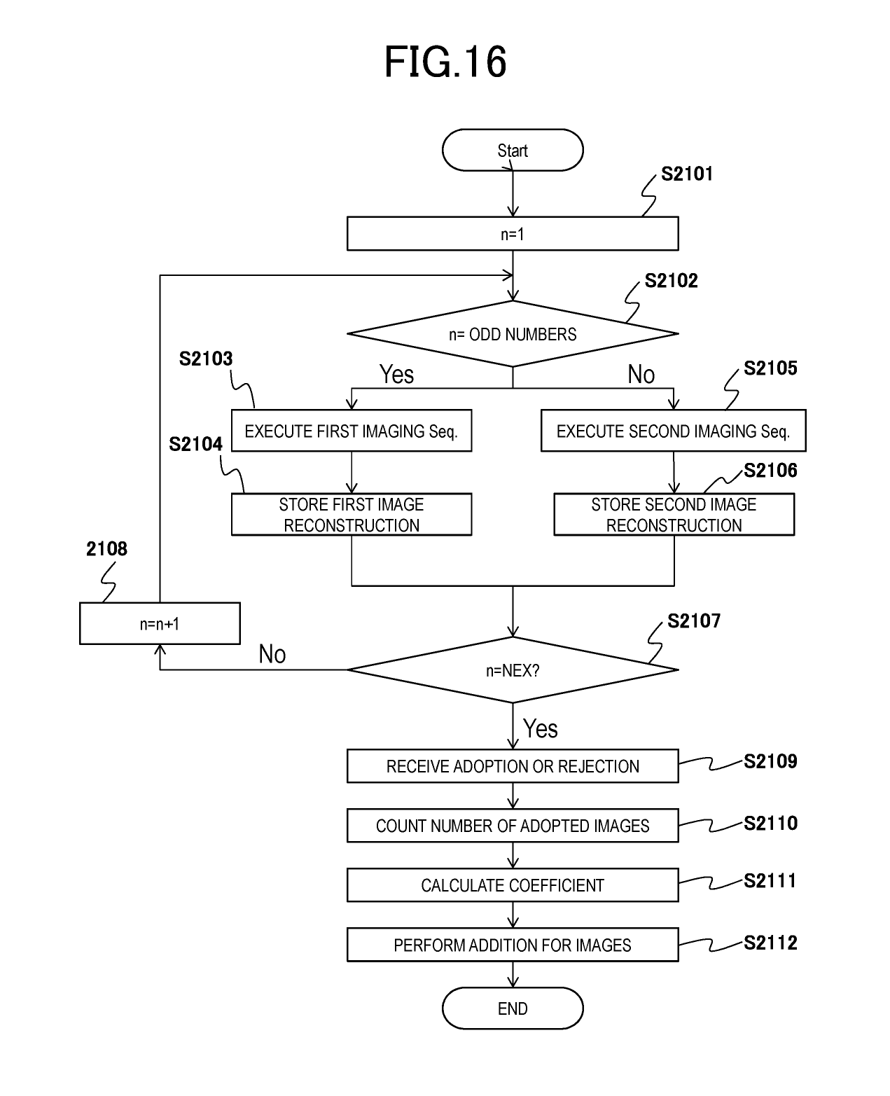

The process flow of addition imaging processing by the entire control unit 112 of the present embodiment will be described using FIG. 16. Similarly to the first embodiment, the addition imaging processing of the present embodiment starts after receiving the setting for the total number of additions NEX as an imaging condition from a user and receiving a command of starting imaging.

First, the measurement section 130 initializes a counter n (n=1) counting the number of measurements, i.e. imaging sequences (Step S2101).

Then, the measurement section 130 determines whether n is odd or even (Step S2102) and executes the first imaging sequence in a case where n is odd (Step S2103). Then, the image reconstruction section 160 reconstructs the first images from the acquired k-space data and store them in the memory 113, the internal storage device 115, or the external storage device 117 (Step S2104).

On the other hand, in a case where n is even, the measurement section 130 executes the second imaging sequence (Step S2105). Then, the image reconstruction section 160 reconstructs the second images from the acquired k-space data and store them in the memory 113, the internal storage device 115, or the external storage device 117 (Step S2106).

The measurement section 130 repeats the above processes until images are acquired by the total number of additions NEX specified as an imaging condition (Steps S2107 and S2108).

After acquiring the images by the total number of additions NEX (n=NEX) (Step S2107), the reception section 170 displays all the acquired first and second images on the adoption/rejection receiving screen 700 and receives adoption or rejection from a user (Step S2109). Then, the reception section 170 counts the number of the adopted first and second images respectively (Step S2110) and notifies the coefficient calculation section 140 of the number.

The coefficient calculation section 140 uses the number of the adopted first and second images respectively in order to calculate the second weight coefficient C2 (Step S2111). Then, the addition section 150 adds all the second images to all the first images while multiplying the second weight coefficient C2 by each of the second images, acquires addition images (Step S2112), and then ends the processes.

Although the reception section 170 receives adoption or rejection here after all the images by the number of NEX are reconstructed and displayed on the adoption/rejection receiving screen 700, the procedure is not limited to this. For example, it may be configured so that the reception section 170 displays images on the display device 118 and receives adoption or rejection each time the image reconstruction section 160 reconstruct the images.

As described above, the MRI apparatus 100 of the present embodiment comprises the reception section 170 that presents the first and second data to a user and receives a choice of adoption or rejection in addition to the measurement section 130, the coefficient calculation section 140, the addition section 150 that the first embodiment comprises. Then, the addition section 150 adds the first data that is the adopted first data and multiplied by the first weight coefficient C1 to the second data that is the adopted second data and multiplied by the second weight coefficient C2.

For example, in case of addition imaging in EPI imaging of the body trunk, images whose image quality is considerably deteriorated due to the body motion are excluded from a plurality of acquired images, the rest of the images are set as adoption images to be adopted for addition, and there can be a case where only the adoption images are added.

In such a case, there can be a case where the number of the first images acquired in a normal imaging sequence does not correspond to the number of the second images acquired in an imaging sequence in which the predetermined component output was inverted in the adoption images. In this case, when all the acquired images are simply added in the conventional manner, errors caused by hardware performance and/or signal fluctuation caused by a hardware control method is not offset, which results in that artifacts remain.

However, according to the method of the above present embodiment, signal intensities of bipolar data such as the total of the first images and the total of the second images are approximately equivalent, and the errors caused by hardware performance and/or the signal fluctuation caused by a hardware control method is appropriately offset.

### Third Embodiment

Next, the third embodiment of the present invention will be described. In the present embodiment, a user determines the number of additions during addition imaging. That is, an addition image is acquired each time an image is acquired and is presented to the user, and the user instructs to end the imaging when the desired image quality is obtained.

The MRI apparatus 100 of the present embodiment basically has the similar configuration to the second embodiment. However, the functions of each part of the entire control unit 112 are different because the methods for determining the number of images to be added are different.

[Functions of Each Part of Entire Control Unit]

The imaging condition setting section 120 of the present embodiment receives imaging conditions from a user through the operation unit 119 and/or the display device 118. Also in the present embodiment, addition imaging is performed similarly to the above respective embodiments. However, the total number of additions is determined by viewing addition images acquired from the user in the present embodiment. Therefore, the total number of additions NEX may not be received as an imaging condition.

The measurement section 130 repeatedly executes an imaging sequence for obtaining data capable of reconstructing one image according to the received imaging condition similarly to the above first and second embodiments. At this time, the first imaging sequence and the second imaging sequence in which the output polarity of hardware components that is a generation source of errors and/or signal fluctuation of the first imaging sequence were inverted in the adoption images are alternately executed.

The image reconstruction section 160 reconstructs images each time the measurement section 130 obtains k-space data. The first images and second images are reconstructed from the k-space data obtained in the first imaging sequence and the second imaging sequence respectively.

The coefficient calculation section 140 calculates the second weight coefficient C2 each time either of the first data (first images) or the second data (second images) is obtained. At this time, the second weight coefficient C2 is calculated so that the total C2 of the second weight coefficients by which the second data (second images) to be added are to be multiplied is equal to the total of the first weight coefficients C1 by which the first data (first images) to be added are to be multiplied.

For example, by setting the first weight coefficient C1 to 1 and the number of reconstructed images acquired until then (the total of the first and second images) to n, the coefficient calculation section 140 calculates the second weight coefficient C2 using the following equation (11).

$$C 2 = \frac{( n - INT ( \frac{n}{2} ) )}{INT ( \frac{n}{2} )} \qquad ( 11 )$$

It is noted that the equation (11) indicates that the total number of additions NEX is set to n in the above equation (1).

The addition section 150 calculates addition data each time the second weight coefficient C2 is calculated. In the present embodiment, addition images are acquired by multiplying the second weight coefficient C2 calculated by the coefficient calculation section 140 by the respective second images acquired until then and adding the respective multiplied second images to all the first images acquired until then.

The reception section 170 presents an image, i.e. the addition data to a user each time the addition data is obtained and receives an instruction of whether or not to end the presentation from the user. The reception section 170 displays the addition images on the display device 118 and receives an instruction of whether or not to end the display.

FIG. 15(b) illustrates an example of an ending reception screen 701 to be displayed on the display device 118 in this case. As illustrated in the present drawing, the ending reception screen 701 comprises an addition image display region 730 that displays addition images and an ending instruction button 740 that receives an ending instruction. The reception section 170 ends the processes after the ending instruction button 740 is pressed down. On the other hand, when the ending instruction button 740 is not pressed down in a predetermined period, the reception section 170 determines that the processes do not need to end and continues the processes.

It is noted that the reception section 170 may be configured so as to receive a pressing down of a continuing instruction button in addition to the ending instruction button 740 in the ending reception screen 701 in order to perform the corresponding process.

[Process Flow]

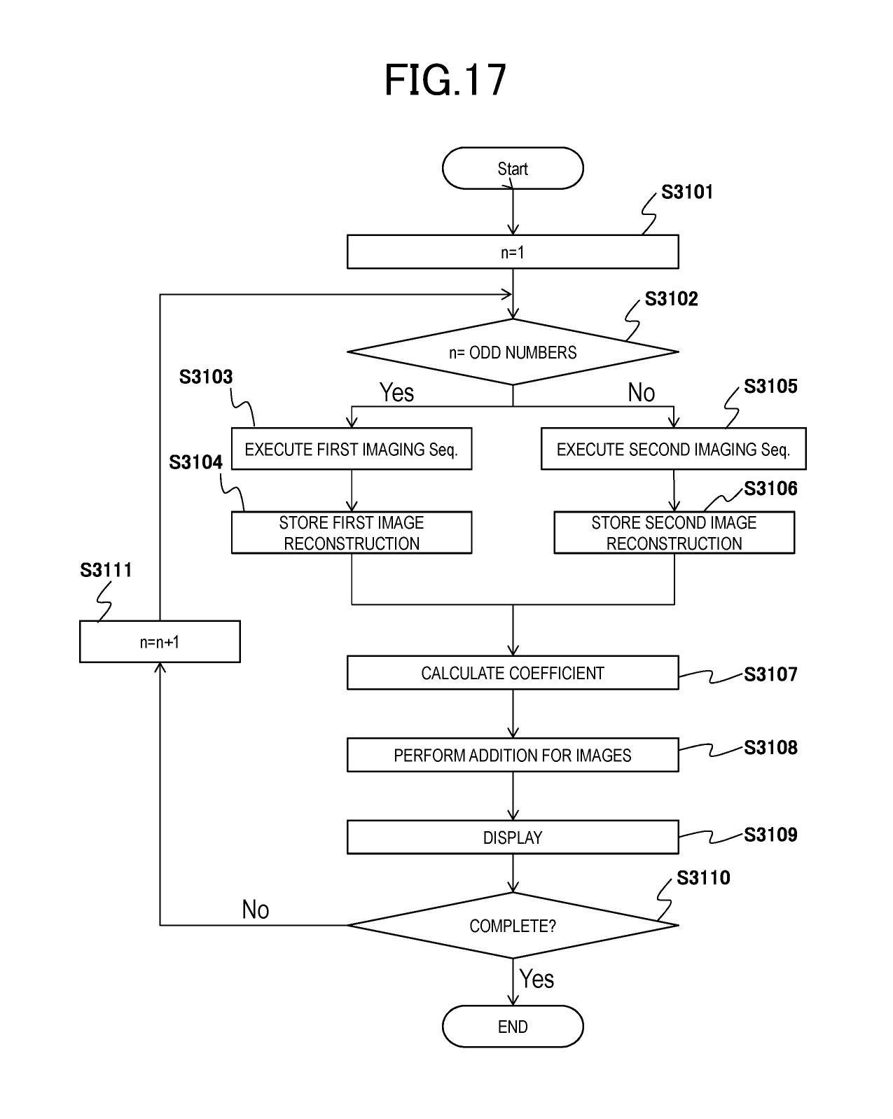

The process flow of addition imaging by the entire control unit 112 of the present embodiment will be described using FIG. 17. Similarly to the second embodiment, the addition imaging processing of the present embodiment is started by a start instruction after an imaging condition is received from a user.

First, the measurement section 130 initializes a counter n (n=1) that counts the number of measurements, i.e. the number of imaging sequences (Step S3101).

Then, the measurement section 130 determines whether n is odd or even (Step S3102) and executes the first imaging sequence in a case where n is odd (Step S3103). Then, the image reconstruction section 160 reconstructs images from the acquired k-space data and stores them in the memory 113, the internal storage device 115, or the external storage device 117 (Step S3104). Then, the procedure proceeds to Step S3107.

On the other hand, when n is even, the measurement section 130 executes the second imaging sequence (Step S3105). Then, the image reconstruction section 160 reconstructs images from the acquired k-space data and stores them in the memory 113, the internal storage device 115, or the external storage device 117 (Step S3106). Then, the procedure proceeds to Step S3107.

The coefficient calculation section 140 calculates the second weight coefficient C2 each time an image is reconstructed (Step S3107). The second weight coefficient C2 to be calculated here is a coefficient by which the second images is to be multiplied when all the first and second images acquired until then are added. Here, a value of the counter n is used for the calculation.

The addition section 150 acquires addition images by multiplying the respective second images by the second weight coefficient C2 and adding all the first and second images acquired until then (Step S3108).

The reception section 170 displays addition images in the ending reception screen 701 (Step S3109) and waits for an instruction from a user. When the reception section 170 receives an ending instruction here, the processes end. On the other hand, in the other case, the counter n is increased by one increment (Step S3111), and the procedure goes back to Step S3102 to repeat the processes.

As described above, the MRI apparatus of the present embodiment comprises the reception section 170 that presents the addition data to a user each time the addition data is obtained and receives an instruction of whether or not to end the presentation from the user, in addition to the measurement section 130, the coefficient calculation section 140, and the addition section 150 that the first embodiment comprises. Then, the coefficient calculation section 140 calculates the second weight coefficient C2 each time either of the first data or the second data is obtained, and the addition section 150 obtains the addition data each time the second weight coefficient is calculated.

According to the present embodiment, the user observes addition images acquired each time the images are added during the addition imaging and ends the addition imaging when it is determined that an SNR reaches a desired level. The number of additions is not necessarily determined at the imaging conditions setting stage before imaging. Because the number of additions is not limited, the imaging can end when a desired SNR is acquired even if the addition number is not even. Therefore, images of a desired SNR can be acquired by the minimum number of additions.

### Modification 1 of Third Embodiment

Although addition is performed after images are reconstructed in the above description, addition may be performed in a state of k-space data in the present embodiment. That is, by executing the first imaging sequence or the second imaging sequence, the coefficient calculation section 140 calculates the second weight coefficient C2 each time either of the first data (first k-space data) or the second data (second k-space data) is obtained. Then, the addition section 150 adds all the first and second k-space data acquired until then each time the second weight coefficient C2 is calculated in order to obtain additional k-space data. At this time, the second k-space data is multiplied by the second weight coefficient C2.

Then, the image reconstruction section 160 reconstructs images from the additional k-space data each time the additional k-space data is obtained in order to acquire addition images. The reception section 170 presents the addition images to a user each time the addition images are reconstructed and receives an end instruction from the user.

### Modification 2 of Third Embodiment

Although the second weight coefficient C2 is calculated each time images or k-space data is obtained in the above description, the procedure is not limited to this. The second weight coefficient C2 is previously calculated for each number of images or k-space data to be obtained and is stored in the internal storage device 115 or the external storage device 117. Also, it may be configured so as to read and use the second weight coefficient C2 during processing. For example, the second weight coefficient C2 may be stored in a table format shown in FIG. 12 corresponding to the above counter n.

### Modification 3 of Third Embodiment

It is noted that the present embodiment may be combined with the second embodiment. That is, images are presented to a user each time the images are acquired in order to determine the whether or not to adopt the images. Then, after addition, the images are presented in order to determine whether or not additional image acquisition is necessary.

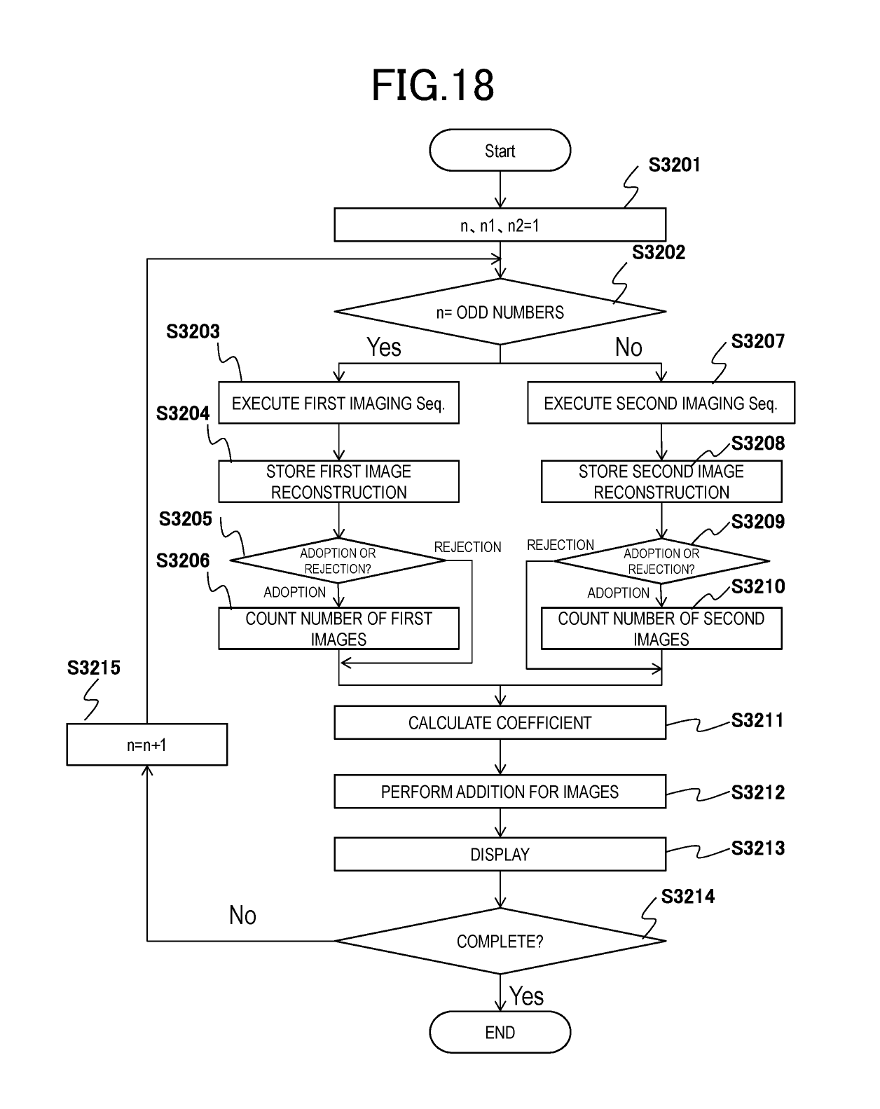

In this case, the flow of the addition imaging processing by the entire control unit 112 will be described using FIG. 18.

First, the counter n counting the number of image acquisitions, the counter N1 counting the number of the first images, and the counter N2 counting the number of the second images are initialized (set to 1) respectively (Step S3201).

The measurement section 130 determines whether n is odd or even (Step S3202) and executes the first imaging sequence in a case where n is odd (Step S3203). Then, the image reconstruction section 160 reconstructs the first images from the obtained k-space data (Step S3204).

The reception section 170 displays the reconstructed first images on the display device 118 and receives whether or not the images are adopted (Step S3205). Then, in case of the adoption, the images are stored in the memory 113, the internal storage device 115, or the external storage device 117 and count the number of the adopted first images by changing the counter N1 of the first images by one increment (Step S3206). It is noted that the images are discarded and the counter N1 is left as is in case of the non-adoption. Then, the procedure proceeds to Step S3211.

On the other hand, in a case where n is even, the measurement section 130 executes the second imaging sequence (Step S3207). Then, the image reconstruction section 160 reconstructs the second images from the obtained k-space data (Step S3208).

The reception section 170 displays the reconstructed second images on the display device 118 and receives whether or not the images are adopted (Step S3209). Then, in case of the adoption, the images are stored in the memory 113, the internal storage device 115, or the external storage device 117 and count the number of the adopted second images by changing the counter N2 of the second images by one increment (Step S3210). It is noted that the images are discarded and the counter N2 is left as is in case of the non-adoption. Then, the procedure proceeds to Step S3211.

The coefficient calculation section 140 calculates the second weight coefficient C2 by which the second images are to be multiplied when the first and second images are added acquired until then each time the images are adopted (Step S3211). Here, values of the counters N1 and N2 are used for calculation according to the above equation (10).

The addition section 150 multiplies the second image by the second weight coefficient C2 and adds the first and second images adopted until then in order to acquire addition images (Step S3212).

The reception section 170 displays addition images in the ending reception screen 701 (Step S3213) and waits for an instruction from a user. When the ending instruction is received here (Step S3214), the processes end. In the other case, the counter n is changed by one increment (Step S3215), the procedure goes back to Step S3202, and then the processes are repeated.

In the above embodiments, all or a part of the functions realized by the entire control unit 112 may be constructed on an information processing device that can transmit and receive data between the MRI apparatus 100 and is independent of the MRI apparatus 100.

### REFERENCE SIGNS LIST

100: MRI apparatus
101: object
102: static magnetic field generation sources
103: gradient magnetic field coils
104: RF transmission coils
105: RF reception coils
106: bed
107: signal processing unit
109: gradient magnetic field power source
110: RF transmission unit
111: sequencer
112: entire control unit
113: memory
114: central processing unit
115: internal storage device
117: external storage device
118: display device
119: operation unit
120: imaging condition setting section
130: measurement section
140: coefficient calculation section
150: addition section
160: image reconstruction section
170: reception section
300: FSE sequence
300inv: FSE sequence
301: excitation RF pulse
302: refocus RF pulse
311: slice selection gradient magnetic field pulse
313: spoiling gradient magnetic field pulse
314: slice selection gradient magnetic field pulse
315: spoiling gradient magnetic field pulse
316: slice encoding gradient magnetic field pulse
317: rewind gradient magnetic field pulse
321: phase encoding gradient magnetic field pulse
322: phase rewind gradient magnetic field pulse
332: frequency encoding gradient magnetic field pulse
341: sampling window
351: echo signal
411: profile
412: profile
421: profile
421a: profile
422: profile
511: profile
512: profile
521: profile
522: profile
531: profile
532: profile
600: EPI sequence
600inv: EPI sequence
601: excitation pulse
602: inversion pulse
611: slice selection gradient magnetic field pulse
612: blip gradient magnetic field pulse
613: readout gradient magnetic field pulse
613a: readout gradient magnetic field pulse
621: echo signal
622: sampling windows
631: MPG pulse
700: adoption/rejection receiving screen
701: ending reception screen
710: image display regions
720: adoption/rejection receiving regions
730: addition image display region
740: ending instruction button

1. A magnetic resonance imaging apparatus comprising:
a measurement section that executes the first imaging sequence and the second imaging sequence in order to obtain first data and second data respectively;
a coefficient calculation section that calculates a second weight coefficient to be multiplied by the second data; and
an addition section that adds the first data multiplied by a predetermined first weight coefficient to the second data multiplied by the second weight coefficient in order to acquire addition data,
wherein the second imaging sequence is an imaging sequence in which the polarity of a predetermined gradient magnetic field pulse was inverted from among a plurality of gradient magnetic field pulses composing the first imaging sequence, and
the coefficient calculation section calculates the second weight coefficient so that the total of the second weight coefficients is equal to the total of the first weight coefficients.

2. The magnetic resonance imaging apparatus according to claim 1,
wherein the first imaging sequence is an FSE (Fast Spin Echo) sequence, and the gradient magnetic field pulse whose polarity is to be inverted includes a phase encoding gradient magnetic field pulse.

3. The magnetic resonance imaging apparatus according to claim 1,
wherein the first imaging sequence is an EPI (Echo Planner Imaging) sequence, and
the gradient magnetic field pulse whose polarity is to be inverted is a read-out gradient magnetic field pulse.

4. The magnetic resonance imaging apparatus according to claim 1,
wherein the first data and the second data are k-space data respectively.

5. The magnetic resonance imaging apparatus according to claim 1,
wherein the first data and the second data are reconstructed images respectively.

6. The magnetic resonance imaging apparatus according to claim 5, further comprising:
a reception section that presents the first data and the second data to a user and receives a choice of adoption or rejection,
wherein the addition section adds the first data that is the adopted first data and multiplied by the first weight coefficient to the second data that is the adopted second data and multiplied by the second weight coefficient.

7. The magnetic resonance imaging apparatus according to claim 5, further comprising:
a reception section that presents the addition data to a user each time the addition data is obtained and receives an instruction of whether or not to end the presentation from the user,
wherein the coefficient calculation section calculates the second weight coefficient each time either of the first data or the second data is obtained, and
the addition section obtains the addition data each time the second weight coefficient is calculated.

8. The magnetic resonance imaging apparatus according to claim 4, further comprising:
an image reconstruction section that reconstructs addition images from the addition data; and
a reception section that presents the addition images to a user each time the addition images are reconstructed and receives an end instruction from the user,
wherein the coefficient calculation section calculates the second weight coefficient each time either of the first data or the second data is obtained,
the addition section obtains the addition data each time the second weight coefficient is calculated, and
the image reconstruction section reconstructs the addition images each time the addition data is obtained.

9. The magnetic resonance imaging apparatus according to claim 1,
wherein the first weight coefficient is set to 1.

10. The magnetic resonance imaging apparatus according to claim 1,
wherein the second data includes a plurality of data, and
the second weight coefficients by which each second data is to be multiplied are all equal.

11. The magnetic resonance imaging apparatus according to claim 2,
wherein the first imaging sequence executes three-dimensional imaging, and
the gradient magnetic field pulse whose polarity is to be inverted further includes a slice encoding gradient magnetic field pulse.

12. The magnetic resonance imaging apparatus according to claim 1,
wherein the gradient magnetic field pulse whose polarity is inverted is a gradient magnetic field pulse that generates at least either of errors caused by hardware performance or signal fluctuation caused by a hardware control method.

13. A magnetic resonance imaging apparatus comprising:
a measurement section that executes a first imaging sequence and a second imaging sequence in order to obtain first data and second data;
a coefficient calculation section that calculates a second weight coefficient by which the second data is to be multiplied; and
an addition section that adds the first data to the second data multiplied by the second weight coefficient in order to acquire addition data,
wherein the second imaging sequence is an imaging sequence in which the polarity of a predetermined gradient magnetic field pulse was inverted from among a plurality of gradient magnetic field pulses composing the first imaging sequence, and
the coefficient calculation section calculates the second weight coefficient so that the total of the second weight coefficients is equal to the number of the first data.

14. A magnetic resonance imaging method comprising the steps of:
executing a first imaging sequence and a second imaging sequence in order to obtain first data and second data respectively;
determining a first weight coefficient and a second weight coefficient respectively so that the total of the first weight coefficients by which the first data are to be multiplied are equal to the total of the second weight coefficients by which the second data are to be multiplied; and
adding the first data multiplied by the first weight coefficient to the second data multiplied by the second weight coefficient in order to acquire reconstructed images,
wherein the second imaging sequence is an imaging sequence in which the polarity of a predetermined gradient magnetic field pulse was inverted from among a plurality of gradient magnetic field pulses composing the first imaging sequence.

15. The magnetic resonance imaging method according to claim 14,
wherein the gradient magnetic field pulse whose polarity is inverted is a gradient magnetic field pulse that generates at least either of errors caused by hardware performance or signal fluctuation caused by a hardware control method.
